(19) United States
(12) Patent Application Publication
(10) Pub. No.: US 2026/0010486 A1
(43) Pub. Date: Jan. 8, 2026

(54) DMA Controller Architecture for Receiving Requests from Non-host Devices

(71) Applicant: DreamBig Semiconductor, Inc., San Jose, CA (US)

(72) Inventors: Linghe Wang, Austin, TX (US); Brian S. Hausauer, Austin, TX (US); David Arditti Ilitzky, Guadalajara (MX); Kenneth J. Clark, Dripping Springs, TX (US); David J. Maguire, Volente, TX (US)

(21) Appl. No.: 19/305,614

(22) Filed: Aug. 20, 2025

Related U.S. Application Data
(62) Division of application No. 19/237,999, filed on Jun. 13, 2025.
(60) Provisional application No. 63/667,695, filed on Jul. 4, 2024.

(51) Int. Cl. G06F 12/1081; G06F 12/02; G06F 13/16

(52) U.S. Cl. CPC G06F 12/1081; G06F 12/0246; G06F 13/1668

(57) ABSTRACT

A chiplet hub for interconnecting a series of connected chiplets and internal resources. An HBM is mounted on top of the chiplet hub to provide multiple party access to the HBM and to save System in Package (SIP) area. The chiplet hub can form system instances to combine connected chiplets and internal resources, with the system instances being isolated. One type of system instance is a private memory system instance with private memory gathered from multiple different memory devices. The chiplet hubs can be interconnected to form a clustered chiplet hub to provide for a larger number of chiplet connections and more complex system. A DMA controller can receive DMA service requests from devices other than a system hosted, including in cases where the chiplet hub is non-hosted.

### CROSS-REFERENCE

This application is a divisional of U.S. application Ser. No. 19/237,999, filed Jun. 13, 2025, which claims priority to U.S. Provisional Application Ser. No. 63/667,695, filed Jul. 4, 2024, the contents of which are incorporated herein in their entirety by reference.

### RELATED CASES

This application is related to application Ser. No. ______, attorney docket number 110-0016US, entitled “Chiplet Hub with Multi-Unit Accessible HBM;” application Ser. No. ______, attorney docket number 110-0017US, entitled “Chiplet Hub with Private Memory Space Formed from Multiple Memories;” application Ser. No. ______, attorney docket number 110-0018US, entitled “Clustered Chiplet Hubs;” and application Ser. No. ______, attorney docket number 110-0019US, entitled “Chiplet Hub Providing Multiple Isolated Interconnect Types,” all filed on Aug. 20, 2025.

### TECHNICAL FIELD

The technical field relates to chiplet technology used to combine semiconductor chips into larger functional devices.

### BACKGROUND

Modern graphical processor units (GPUs) contain 100 billion transistors and may have a die size in the region of 750 mm². At this level and given the extremely small geometries being used to form modern semiconductors, yield becomes a very large problem, which increases cost. Modern communication links exceed 800 Gbps. But the electronics for the communication links are very different from the electronics of the GPU, based on the limits of the semiconductors and the needed properties of the device. This requires multiple chips because of the process differences and use cases. Systems on a Chip (SoCs) are semiconductors that integrate many different functions into a single integrated circuit, functions such as computing, communications, memory, graphics and video. Because only a limited number of semiconductor methods maybe used in a single die, an SoC often has portions not optimized for the function, reducing performance and increasing costs. Further, designing and developing a large, complex SoC is a major undertaking, done at great expense and with many man-hours.

To address these problems, chiplet technology was developed. Chiplets are smaller, more specialized integrated circuits that are combined to produce larger systems. Chiplets have smaller die sizes than monolithic devices such as GPUs and SoCs. This increases yield. Chiplets can also use a semiconductor process optimized for the chiplet function, therefore increasing the performance of the chiplet function as compared to an integrated version. Devices formed from a collection of chiplets can be cheaper to produce and have higher performance than an equivalent monolithic device.

While chiplets are being widely used, the great majority of chiplet-based devices are formed using proprietary chiplet interconnections. This greatly limits the number of parties that can develop chiplet-based systems to just a few large manufacturers. Therefore, the advantages of chiplet-based systems are not being realized by small to medium entities, forcing those small to medium entities to remain using more conventional approaches, even though lower performance and more expensive.

### BRIEF DESCRIPTION OF THE DRAWINGS

For illustration, there are shown in the drawings certain examples described in the present disclosure. In the drawings, like numerals indicate like elements throughout. The full scope of the inventions disclosed herein are not limited to the precise arrangements, dimensions, and instruments shown. In the drawings:

FIG. 1 is a block diagram of a system formed using discrete devices and a system in a package (SiP), which is based on the use of a chiplet hub and special function chiplets.

FIG. 2 is a block diagram of the system of FIG. 1 illustrating independent system instances in the SiP.

FIG. 3 is a diagram illustrating the relationships of the system instances of FIG. 2 with the discrete devices and particular devices of the SiP and chiplet hub of FIG. 1.

FIG. 4 is a block diagram illustrating the interfaces between the chiplet hub and the various chiplets in the system of FIG. 1.

FIG. 5 is a block diagram of a hub manager function for the system of FIG. 1.

FIG. 6A1 is a block diagram of a first internal host system instance of FIG. 2.

FIG. 6A2 is a block diagram of a variation of the first internal host system instance of FIG. 6A1.

FIG. 6B is a block diagram of a second internal host system instance of FIG. 2.

FIG. 6C is a block diagram of a first non-hosted system instance of FIG. 2.

FIG. 6D is a block diagram of a second non-hosted system instance of FIG. 2.

FIG. 6E is a block diagram of an externally hosted system instance of FIG. 2.

FIG. 6F is a block diagram of a private memory logical system instance of FIG. 2.

FIG. 6G1 is a block diagram of SRAM 110 and related system instances and DRAM 142 and related system instances.

FIG. 6G2 is a block diagram of accelerator 1 118 and related system instances.

FIG. 6H is a block diagram of a chassis logical fabric of FIG. 2.

FIG. 7A is a block diagram illustrating the connections of a hub DMA (HDMA) controller to the system instances and devices of FIG. 2.

FIG. 7B1 is a ladder diagram of the operation of the HDMA controller according to a first protocol.

FIG. 7B2 is the ladder diagram of FIG. 7B1 modified for operation with multiple system instances.

FIG. 7C is a block diagram of the first HDMA control protocol.

FIG. 7D1 is a ladder diagram of the operation of the HDMA controller according to a second protocol.

FIG. 7D2 is the ladder diagram of FIG. 7D1 modified for operation with multiple system instances.

FIG. 7E is a block diagram of the second HDMA control protocol.

FIG. 8A is an illustration of mapping of memory requests from requester devices to memory devices.

FIG. 8B is an illustration of the composition of a memory packet transferred between a requesting device and a memory.

FIG. 8C is an illustration of the composition of a communication packet transferred between a requesting device and receiving device.

FIG. 8D is an illustration of the composition of a packet being tunneled between a requesting device and receiving device.

FIG. 9A is a block diagram of a device to device (D2D) connection according to the present invention.

FIG. 9B is a block diagram of the link services on one side of a D2D link according to the present invention.

FIG. 9C is an illustration of two examples of D2D connections.

FIG. 10A is a block diagram illustrating the interconnection of multiple chiplet hubs of FIG. 1 according to the present invention.

FIG. 10B is a flowchart of initialization of the chiplet hubs of FIG. 10A.

FIG. 10C is a block diagram illustrating locality of memory with regard to requesting devices according to the present invention.

FIG. 11A is a diagram illustrating an exemplary physical layout of a chiplet hub, high bandwidth memory (HBM) and child chiplets according to the present invention.

FIG. 11B is a side view of a chiplet hub and an HBM memory stack according to a first embodiment of the present invention.

FIG. 11B1 is an illustration of a conductive path through the chiplet hub die.

FIG. 11C is a side view of a chiplet hub and an HBM memory stack according to a second embodiment of the present invention.

FIG. 11D is a block diagram of the arrangement elements of the chiplet hub of FIG. 11B.

FIG. 11E is a block diagram of the arrangement of the elements chiplet hub of FIG. 11C.

### DETAILED DESCRIPTION OF THE EXAMPLES

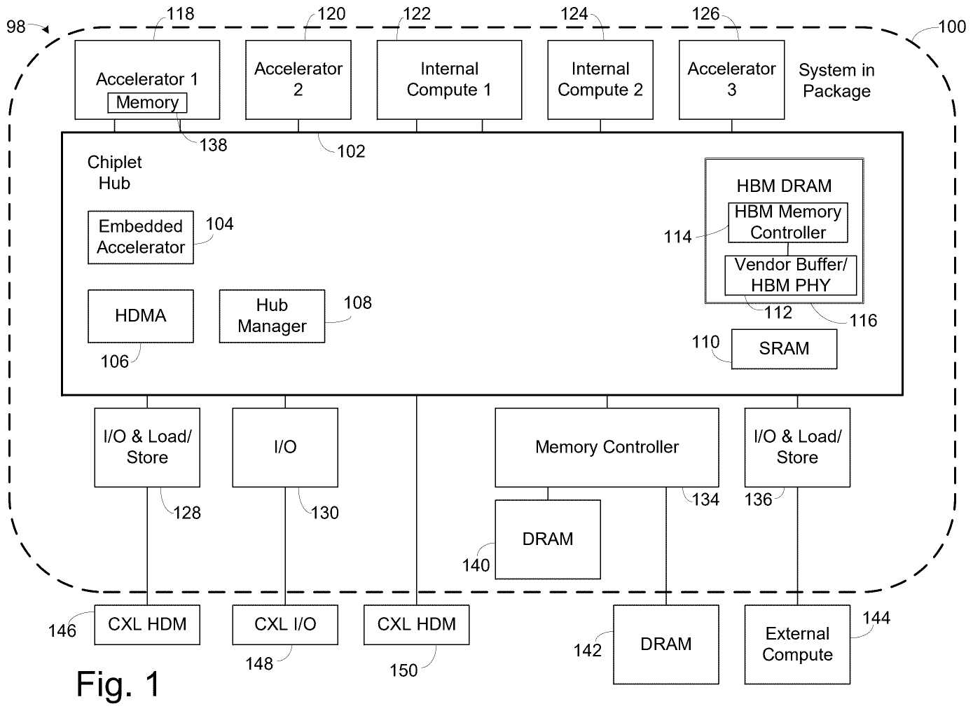

Referring now to FIG. 1, a system 98 is illustrated which includes a system in a system in package (SiP) 100 and a chiplet hub 102. The chiplet hub 102 includes an embedded accelerator 104, an HDMA controller 106, a hub manager 108, SRAM 110, vendor buffer/HBM PHY 112 connected to an HBM memory controller 114, with a double line indicating the HBM DRAM 116, which is located over the chiplet hub 102. Various chiplets are connected to the chiplet hub 102. For example, a first accelerator chiplet 118 is connected to the chiplet hub 102, as is a second accelerator chiplet 120, a first internal compute unit chiplet 122, a second internal compute unit chiplet 124, a third accelerator chiplet 126, an I/O and load and store chiplet 128, an I/O chiplet 130, a memory controller chiplet 134, and an I/O and load and store chiplet 136. DRAM 140 is connected to the memory controller 134 and is located inside the SiP 100 while the DRAM 142 is connected to the memory controller 134 but is located outside of the SiP 100. An external compute 144 is connected to the I/O and load and store chiplet 136. A CXL host-managed device memory (HDM) 146 is connected to the first I/O and load and store chiplet 128. A CXL I/O 148, such as a network interface card (NIC), is connected to the I/O chiplet 130. A CXL HDM 150 is connected to the chiplet hub 102.

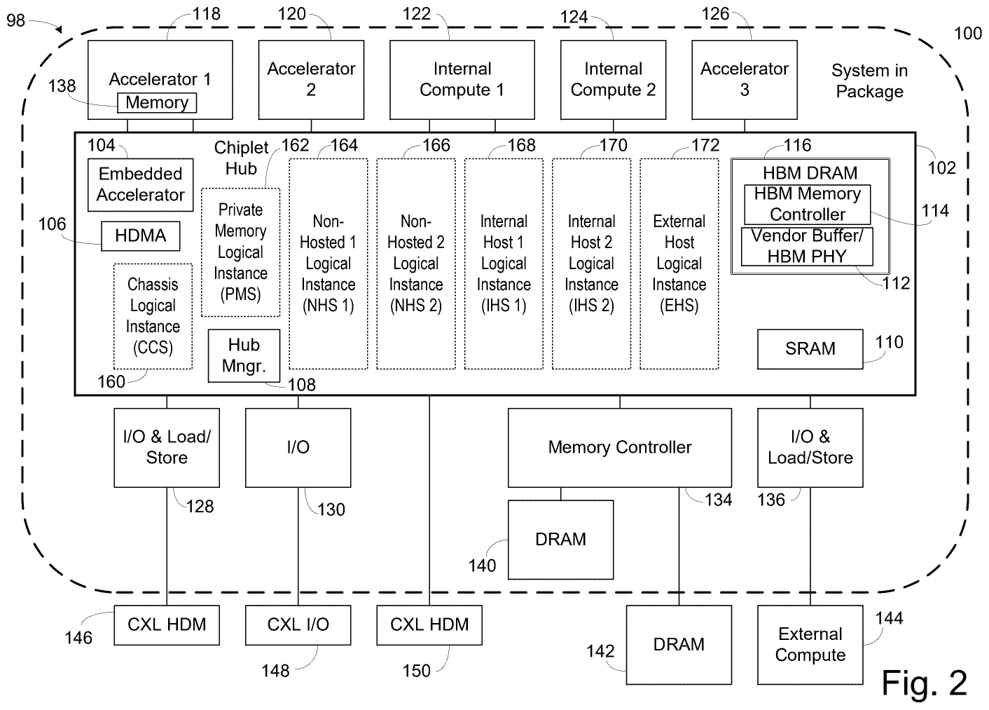

Referring now to FIG. 2, the devices shown in FIG. 1 are repeated with the addition of system instances which are used to interconnect the various devices and memories. A chassis logical system instance (CCS) 160 is provided to illustrate the interconnections of the hub manager 108 and the remaining devices for purposes of configuring the various devices and transferring various messages. A private memory logical system instance (PMS) 162 is illustrated to provide a private memory area for a memory requesting device. A first non-hosted logical system instance (NHS 1) 164 is illustrated as a first example of a non-hosted system instance, while a second non-hosted logical system instance (NHS 2) 166 is illustrated to show a second example of a non-hosted system instance. Similarly, a first internal host logical system instance (IHS 1) 168 is shown in conjunction with a second internal host logical system instance (IHS 2) 170. An external host logical system instance (EHS) 172 is shown for the use with the external compute 144.

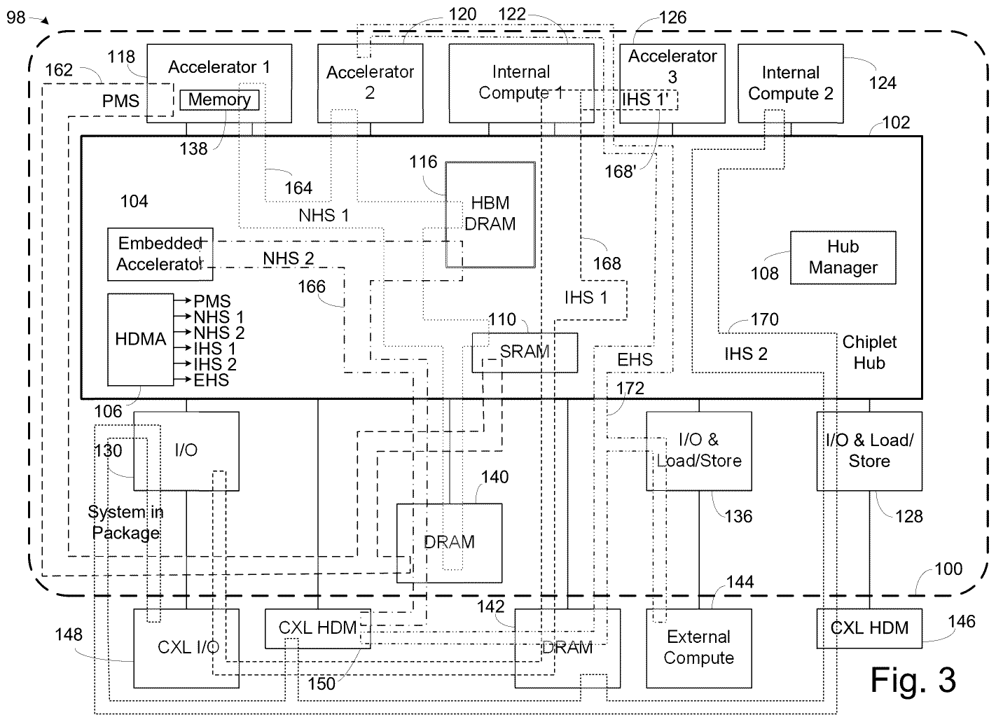

FIG. 3 maps one exemplary example of the system instances of FIG. 2 to the various devices of FIGS. 1 and 2. The mapping is shown by a series of dashed lines which overlay and interconnect various of the devices. IHS 1 168 is formed by the combination of internal compute 1 122, SRAM 110, DRAM 142, I/O 130 and CXL I/O 148. A slight variant of IHS 1, IHS 1′ adds accelerator 3 126 to IHS 1 168. IHS 2 170 is formed by internal compute 2 124 in conjunction with I/O and load and store 128, CXL HDM 146, DRAM 142, I/O 130, CXL I/O 148 and CXL HDM 150. NHS 1 164 is formed by the combination of accelerator 1 118, accelerator 2 120, HBM DRAM 116, SRAM 110, and DRAM 140. NHS 2 166 is formed by embedded accelerator 104, HBM DRAM 116, DRAM 140 and CXL HDM 150. EHS is formed by the combination of accelerator 2 120, DRAM 142, I/O and load and store chiplet 136, external compute 144, and CXL HDM 150. PMS 162 is formed by accelerator 1 118, DRAM 140 and SRAM 110. The logical arrangements shown in FIG. 3 will form the basis of various detailed examples provided in the later Figures and descriptions. It is understood that many other logical configurations and arrangements are possible, combining and sharing devices and memories as needed. It is also understood that all system configurations support multiple systems instances of all given types, except for CCS system instances, and multiple types of system instances, all coexisting and isolated.

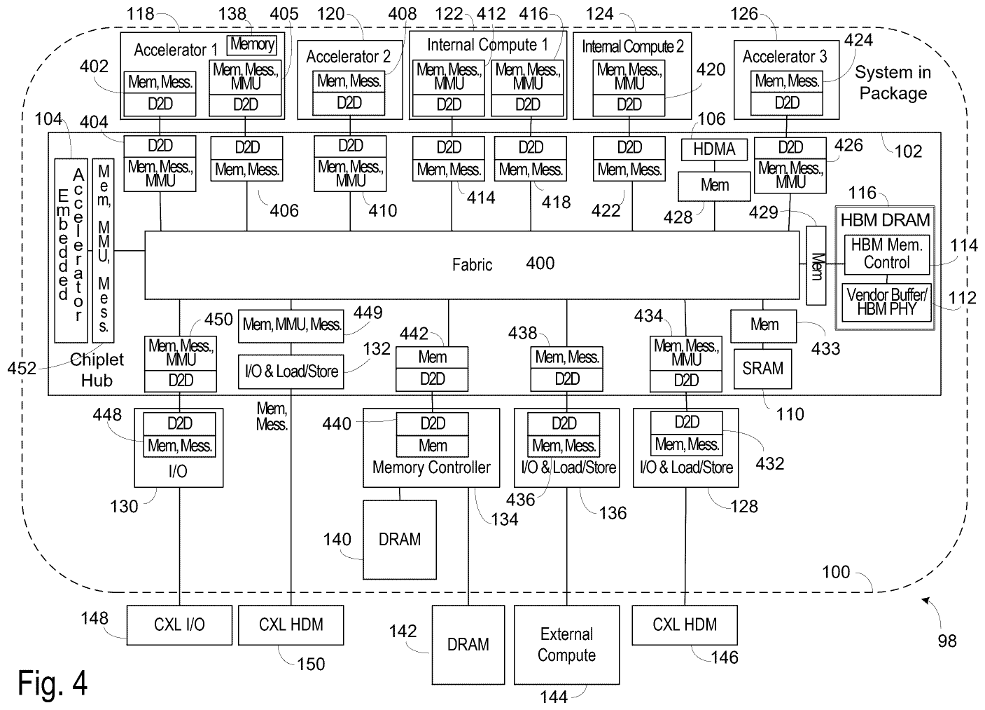

Referring now to FIG. 4, a central fabric 400 is illustrated. The fabric 400 forms an interconnect for memory and inter-device communication transactions in the chiplet hub 102. FIG. 4 illustrates the interfaces between the particular attached chiplet or internal devices and the fabric as well as the interfaces internal to the various attached chiplets. Accelerator 1 118 includes a first memory and messaging adapter and a D2D PHY 402 connected across a die to die (D2D) link to a D2D PHY and a memory, memory management unit (MMU) and messaging adapter 404, which is connected to the fabric 400. For this portion of the description, message is used to refer to various communications that can occur between devices and is not generally related to configuration or HDMA operations. Examples include inter-device messages, transaction completions, interrupts, and snoop requests indications. Accelerator 1 118 includes a memory, MMU and messaging adapter and D2D PHY 405 connected across a D2D link to a D2D PHY and memory and messaging adapter 406, which is connected to the fabric 400. Accelerator 2 120 includes a memory and messaging adapter and D2D PHY 408 connected across a D2D link to a D2D PHY and memory, MMU and messaging adapter 410, which is connected to the fabric 400. Internal compute 1 122 includes a memory, MMU and messaging adapter and D2D PHY 412 connected across a D2D link to a D2D PHY and memory and messaging adapter 414, which is connected to the fabric 400. The internal compute 1 122 includes a second memory, MMU and messaging adapter and D2D PHY 416 which is connected across a D2D link to a D2D PHY and memory and messaging adapter 418, which is connected to the fabric 400. Internal compute 2 124 includes a memory, MMU and messaging adapter and D2D PHY 420 which is connected across the D2D link to a D2D PHY and memory and messaging adapter 422, which is connected to the fabric 400.

The accelerator 3 126 includes a memory and messaging adapter and D2D PHY 424 which is connected across a D2D link to a D2D PHY and memory, MMU and messaging adapter 426, which is then also connected to the fabric 400. The HDMA controller 106 includes a memory adapter 428 connected to the fabric 400. The HBM memory controller 114 is connected to a memory adapter 429, which is connected to the fabric 400. The SRAM 110 is connected to a memory adapter 433, which is connected to the fabric 400. The I/O and load and store chiplet 128 connected to the CXL HDM 146 includes a memory and messaging adapter and D2D PHY 432 which is connected across a D2D link to a D2D PHY and memory, MMU and messaging adapter 434 inside the chiplet hub 102, with the D2D PHY and memory, MMU and messaging adapter 434 connected to the fabric 400. The I/O and memory load store chiplet 136 connected to the external compute 144 includes a memory and messaging adapter and D2D PHY 436 which is connected over a D2D link to a D2D PHY and memory and messaging adapter 438 in the chiplet hub 102, the D2D PHY and memory and messaging adapter 438 connected to the fabric 400. The memory controller 134 includes a memory adapter and D2D PHY 440 connected across the D2D link to a D2D PHY and memory adapter 442 which is connected to the fabric 400. An I/O and load and store unit 132 is located inside the chiplet hub 102 and connects to the CXL HDM 150 using a CXL link. The I/O and load and store unit 132 is connected to a memory, MMU and messaging adapter 449, which is connected to the fabric 400. The I/O 130 which is connected to the CXL I/O device 148 includes a memory and messaging adapter and D2D PHY 448 which connects across a D2D link to a D2D PHY and memory, MMU and messaging adapter 450, which is connected to the fabric 400. The embedded accelerator 104 is attached to a memory, MMU and messaging adapter 452 which is connected to fabric 400.

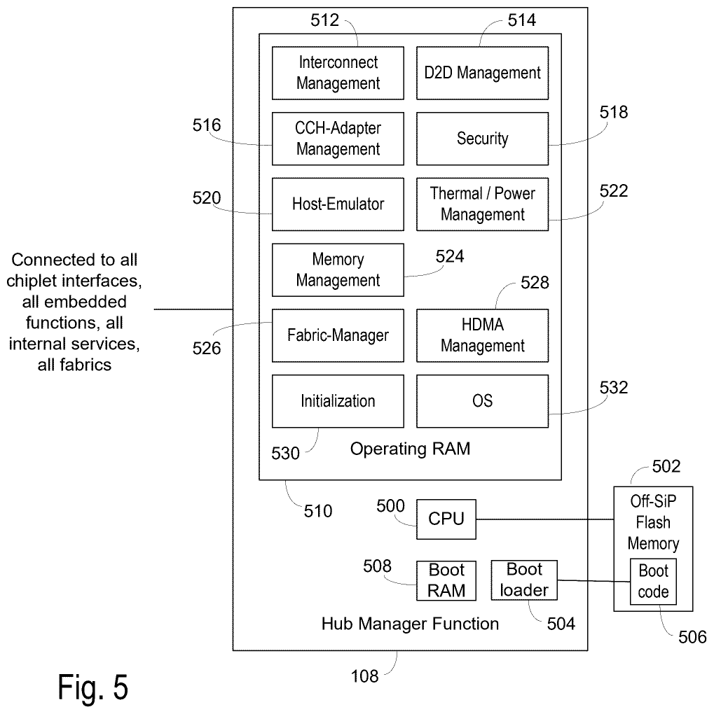

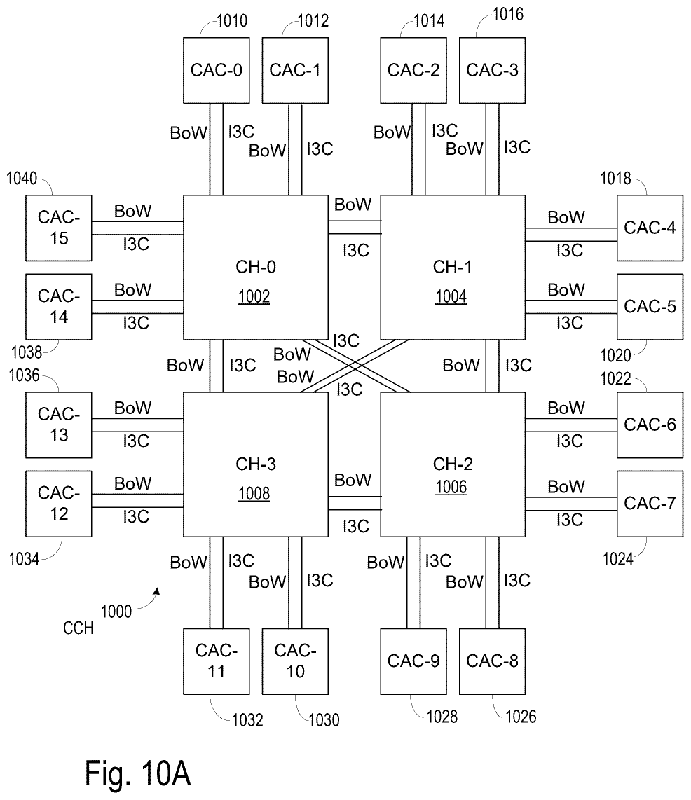

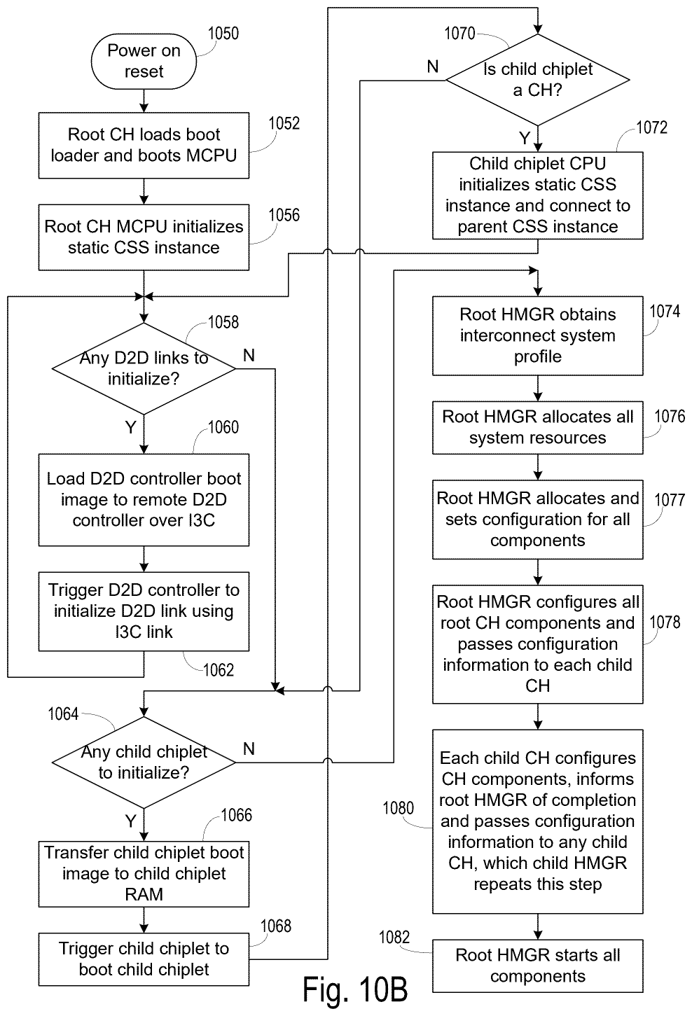

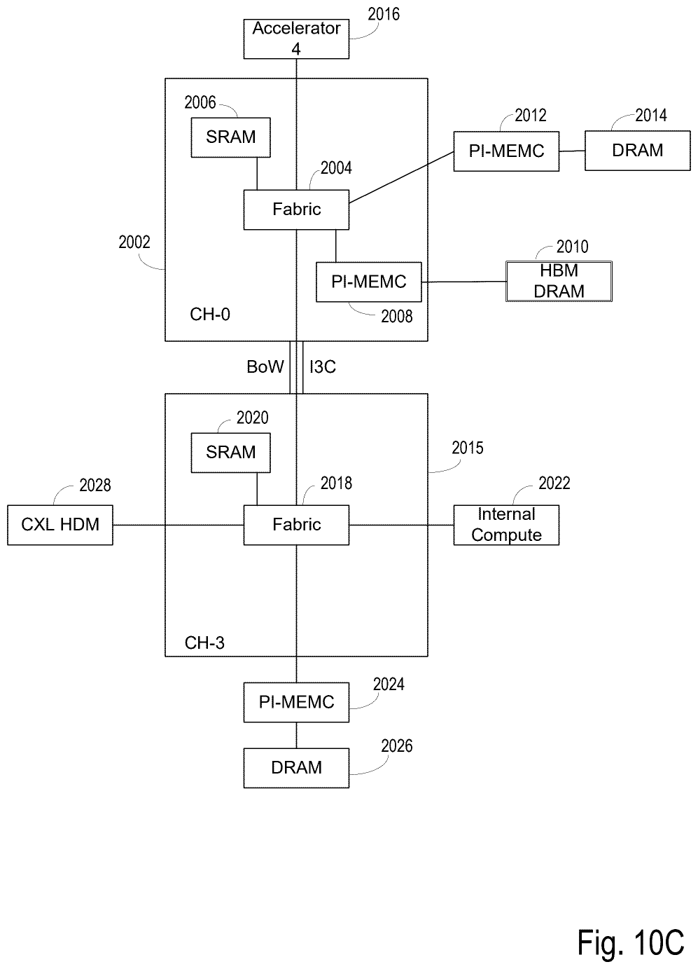

Referring now to FIG. 5, the hub manager 108 is illustrated in more detail. The hub manager 108 includes a CPU 500 to perform the necessary management operations. The CPU 500 is connected to an off-SiP flash memory 502 which contains the configuration information for the interconnection and operation of the various devices and the firmware executed by the CPU 500 to perform hub manager 108 operations. A boot loader 504 is used to commence operation of the system 98 by obtaining boot code 506 from a secure area in the flash memory 502 and loading it into boot RAM 508, where the boot code 506 is then executed by the CPU 500 to initialize the system as illustrated in FIG. 10B.

The hub manager 108 includes operating RAM 510 which includes various modules which are loaded from the flash memory 502. An interconnect management module 512 manages the operations of and interconnections to the fabric and interconnection and shared operations of a series of interconnected chiplet hubs, as described below. A D2D management module 514 is responsible for configuring the D2D links which connect the chiplet hub 102 to the child chiplets and the link services blocks which connect to the D2D interfaces. A CH adapter management 516 handles pipelines developed between devices and the fabric 400. A security module 518 performs security functions on the various operations which occur inside the system 98. The security operations are omitted in this description for simplicity. A host emulator module 520 is used to emulate a host handling the control-path transaction-flow for CXL HDM devices used as a memory tier. Thermal and power management module 522 is provided to manage the thermal and power operations of the system 98, which is utilized to allow the HBM DRAM 116 to be located on top of the chiplet hub 102. A memory management module 524 is provided to manage the allocations of memory between system instances and devices. A fabric manager module 526 is provided to manage an embedded fabric used with CXL HDM devices as a memory tier, as described below. An HDMA management module 528 is used to manage the HDMA controller 106 as described in more detail below. Initialization module 530 operates to initialize the system 98 and bring up each of the individual chiplet hubs 102 and chiplets. An operating system 532 is provided as well.

It is understood that any of these management functions represented as modules could include hardware offload to improve performance or reduce load on the hub manager 108.

In many embodiments the chiplet hub 102 will include a low-speed serial interface, such as I3C, utilized by the hub manager 108 to receive management instructions and to receive firmware images. In those embodiments, the hub manager 108 will include additional modules for communicating with the external device to receive the management instructions and for downloading and updating contents of the flash memory 502.

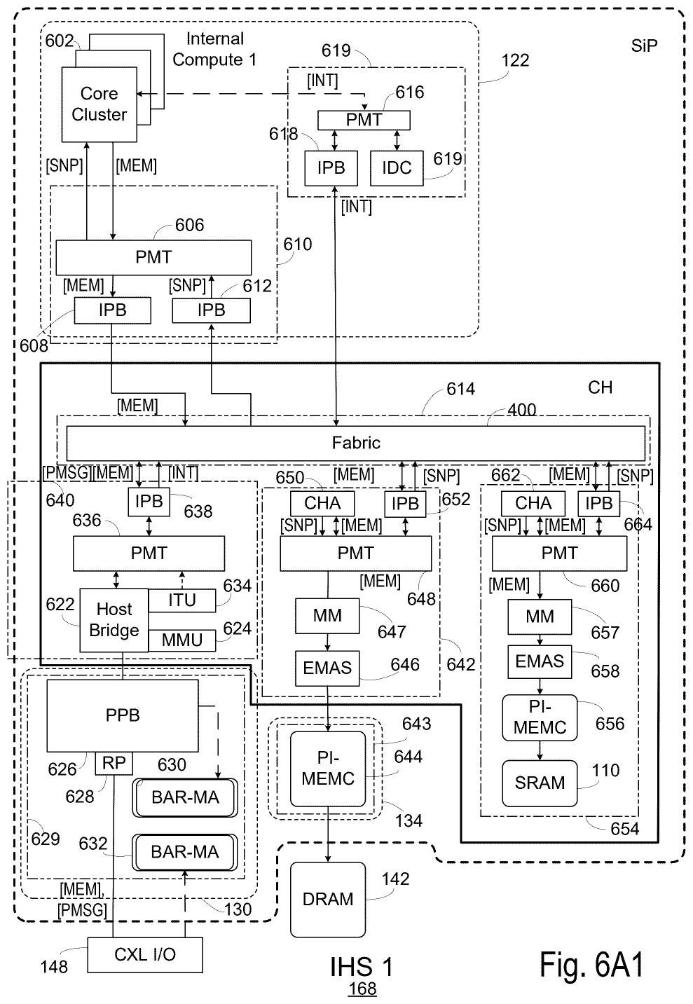

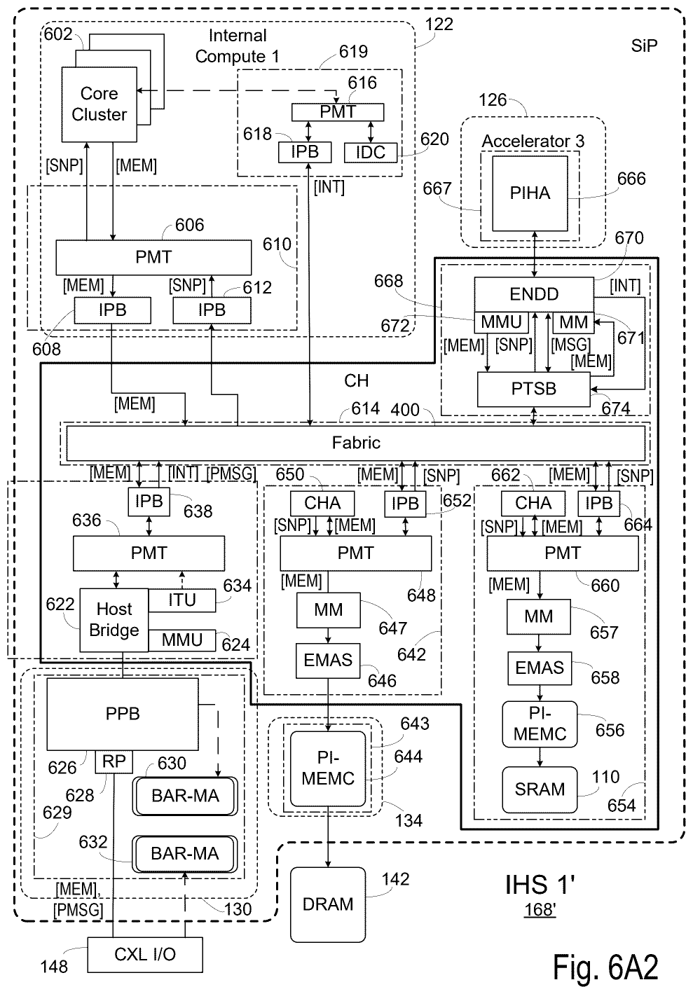

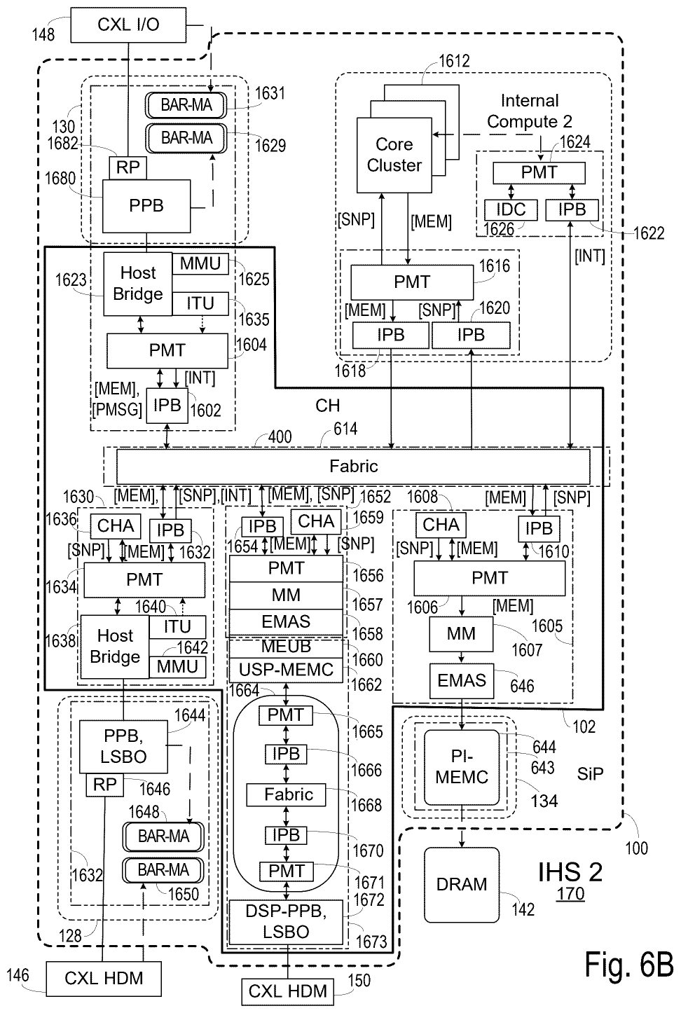

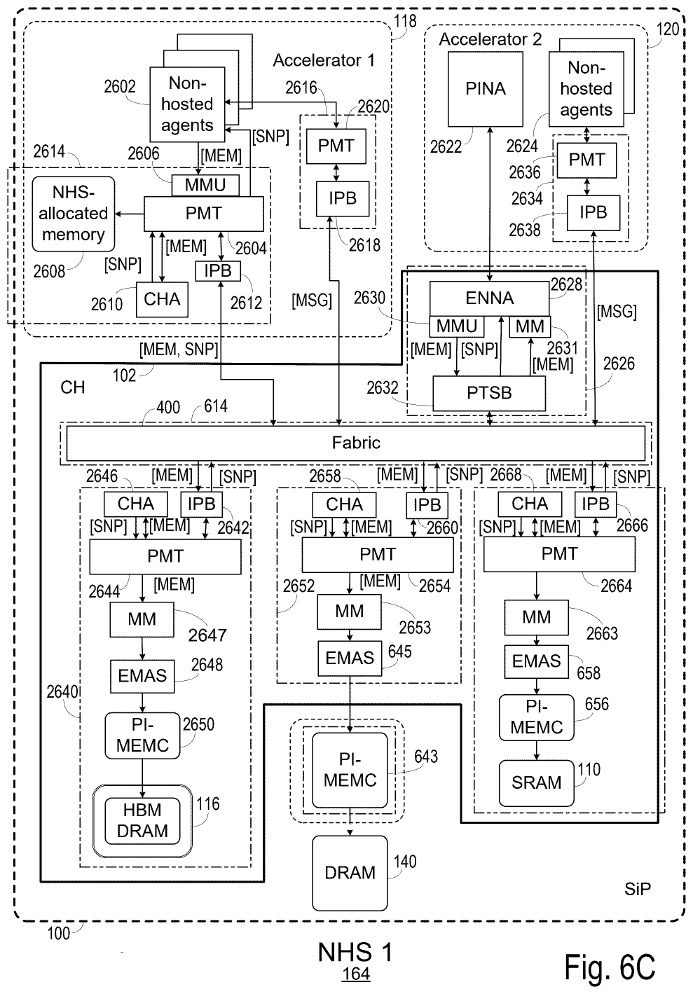

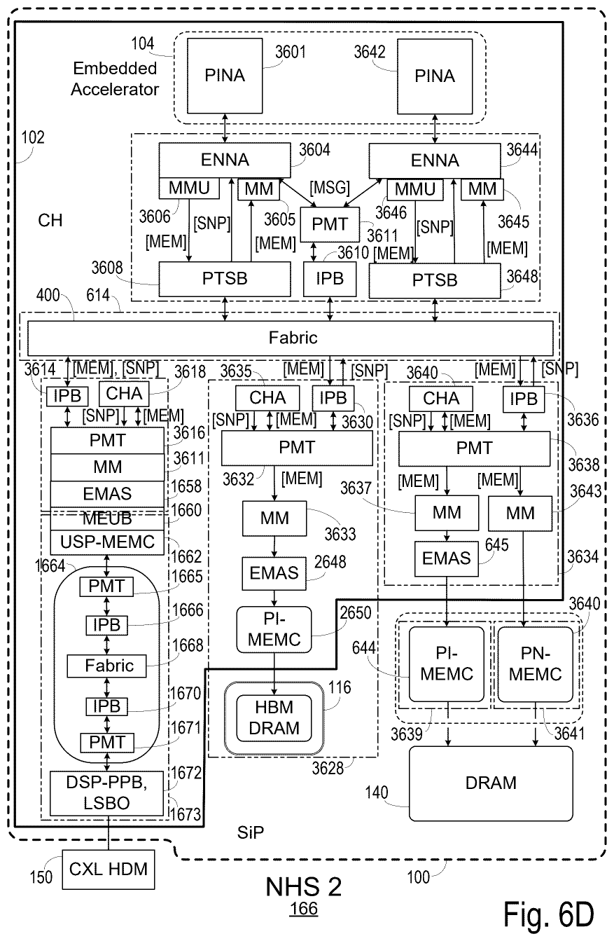

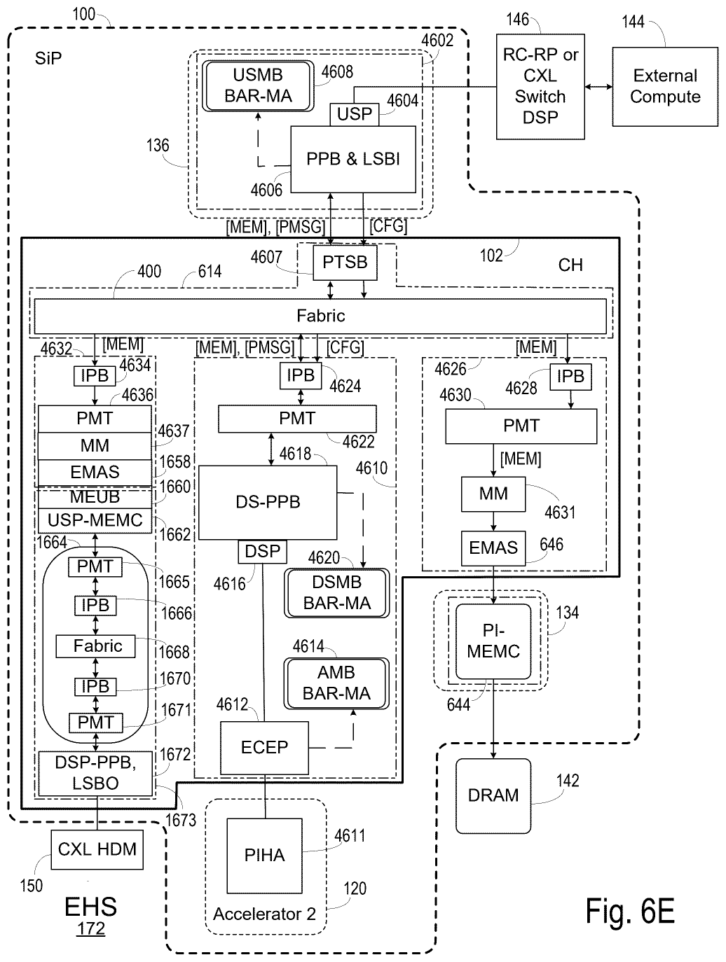

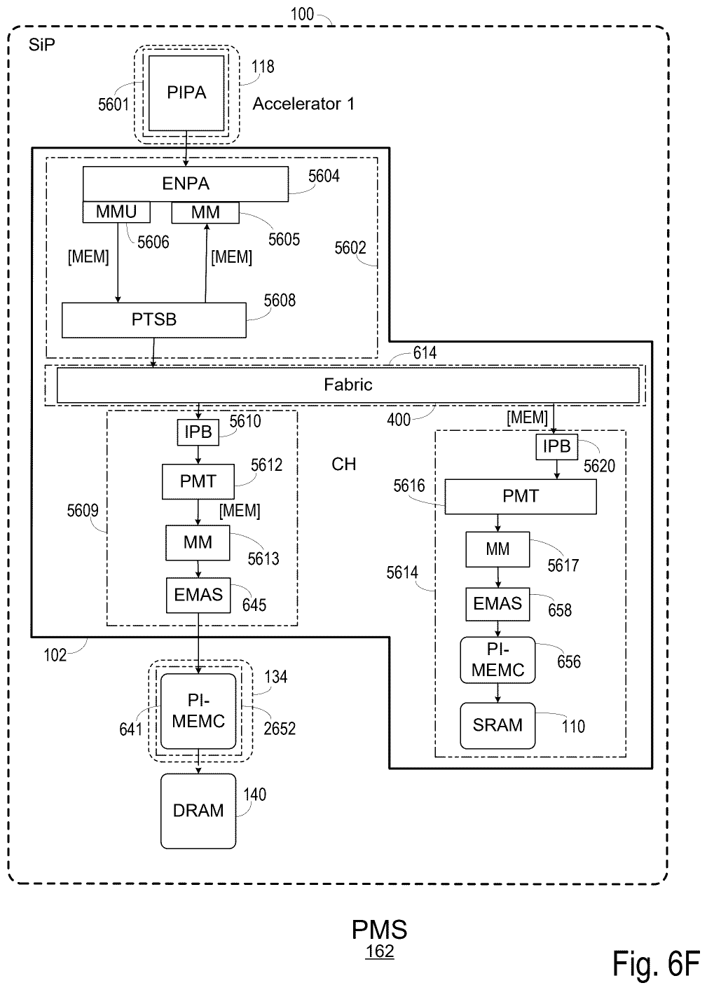

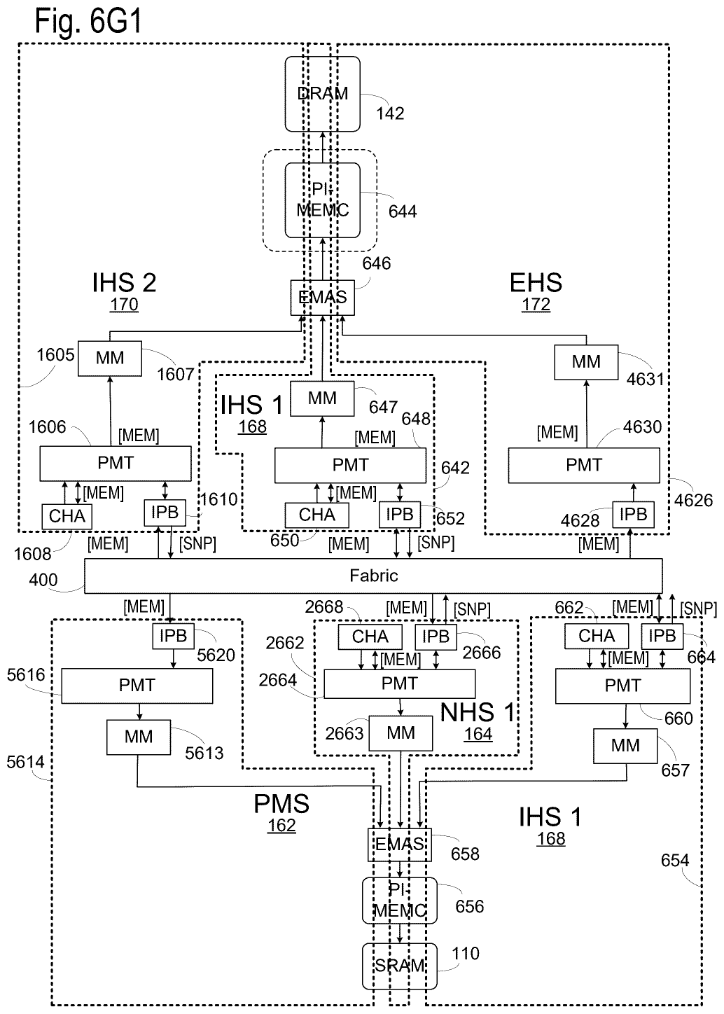

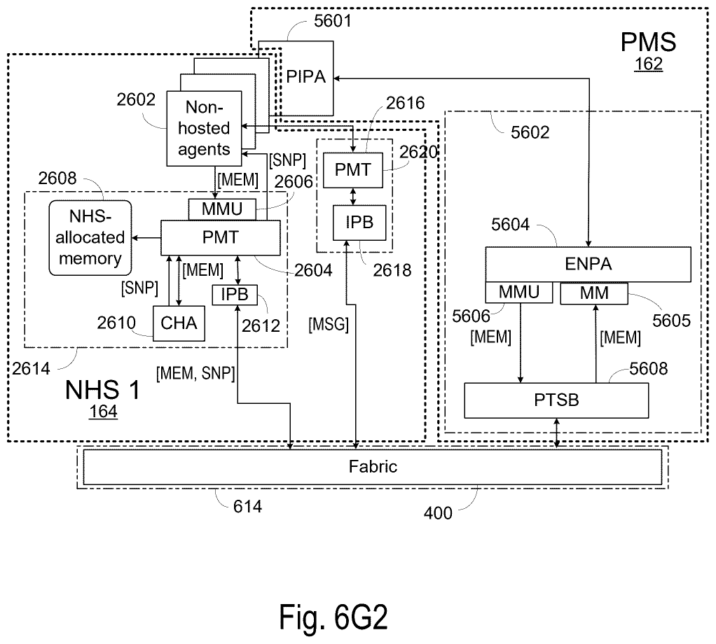

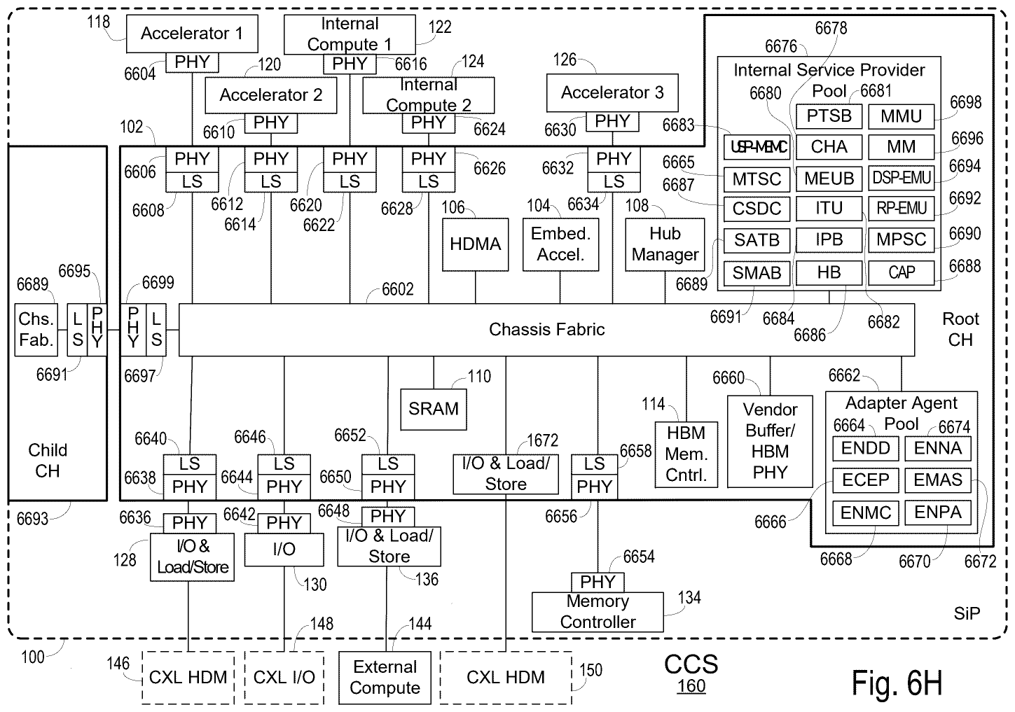

FIG. 6A1 illustrates the IHS 1 168 system instance. IHS 1 168 connects the internal compute 1 122 to the DRAM 142, the SRAM 110, I/O 130 and the CXL I/O device 148. The internal compute 1 122 has a core complex or cluster 602 which performs the basic computing capabilities. The cluster 602 is connected to a PMT or partition mapping table 606. Mapping tables such as PMT 606 are illustrated to provide the routing of various transactions such as snoop and memory transactions, interrupts and messages through the system 98. The PMTs such as PMT 606 and PMT 616 in practice are operations and configurations for an external fabric, which is not explicitly shown, inside Internal Compute 1 122. PMT 606 and PMT 616 are illustrated for explanatory purposes. The PMT 606 forwards snoop transactions to the individual CPUs in the cluster 602 and receives memory transactions from the CPUs in the cluster 602. The PMT 606 is connected to an inter-partition bridge (IPB) 608, which is in turn connected to the fabric 400. The internal compute 1 122 includes a partition 610 which includes the PMT 606, the IPB 608 and an IPB 612. Partition 610 is a partition in IHS 1 168. Partitions such as partition 610 can be viewed as portions of the relevant system instance. Partitions have two basic classes, expander partitions and non-expander partitions. Expander partitions extend the routing functions of the fabric 400 to encompass a group of services, adapters or functions. Expander partitions always include a PMT and an IPB. Non-expander partitions do not perform routing functions but generally designate a device or component for routing to and from that device or component. The fabric 400 is treated as a partition 614 which is used to handle routing between the various partitions in a particular system instance of the multiple system instances of the system 98.

The PMT 606 also receives snoop transactions from an IPB 612 connected to the fabric 400. The PMT 606 routes the snoop transactions received from the fabric 400 into the cluster 602 to the appropriate core. Memory transactions requested by the cluster 602 are provided to the PMT 606 and then to the IPB 608 to the fabric 400.

Interrupts are received from the fabric 400 by an IPB 618 located in partition 619. An interrupt PMT 616 is connected to the IPB 618 and to the cluster 602 to forward interrupts generated by the CPUs in the cluster 602 and received from the fabric 400. An interrupt distribution controller (IDC) 619 is connected to the PMT 616 to manage the flow of interrupts to and from the fabric 400 and cores in the cluster 602, primarily load balancing interrupts between the cores in the cluster 602. The PMT 616 routes the interrupts to either the IPB 618, in which case they are forwarded to the fabric 400 and the final target would be another core cluster (not shown for simplicity) within the same system instance, to the IDC 619 or to the cores in the cluster 602.

Transactions are routed to and through the fabric 400 generally in two different ways. A first way is according to a system instance ID and a memory address when it's a memory transaction. Transactions such as messages, interrupts, snoops and completions are routed through the fabric 400 based on system instance ID and destination ID. For example, if a need for a snoop is determined, the snoop is addressed to the particular device of interest, such as a core in the cluster 602, and routed from the originating device to target core in the cluster 602 based on system instance ID and destination ID. This is in contrast to a memory transaction from the cluster 602, would use system instance ID and memory address in the respective partition. Translation of and changes to memory addresses are discussed below.

This routing based on system instance ID and address or destination ID, in combination with properly assigning address ranges to the system instances and device IDs and translating or mapping addresses to conform with the assigned address ranges allows isolation of the system instances from each other.

The CXL I/O device 148 must connect to a PCIe/CXL root complex. In the case of CXL I/O 148, the I/O 130 includes a root port 628 of a PCI-to-PCI bridge (PPB) 626. A host bridge 622 is provided in the chiplet hub 102 for PCI standard operation, to provide a MEM transaction space, a PCI message (PMSG) transaction space, a PCI config transaction space and an I/O transaction space. The host bridge 622 connects to the PCI-to-PCI bridge 626. An MMU 624 is associated with the host bridge 622 to do address space conversions between the CXL I/O 148 and the IHS 1 168 system instance physical memory space. Because both the root port PPB 626 and CXL I/O device 148 operate through memory windows or BARs as normal for PCI transactions, memory BARs are provided, bar 630 being the window view from the host system for PPB 626 and bar 632 being the window view from the host system for CXL I/O device 148. An interrupt translation unit (ITU) 634 is connected to the host bridge 622 to convert PCI interrupts to native interrupts of IHS 1 168 system instance. The ITU 634 and the host bridge 622 are connected to a PMT 636 which routes between the host bridge 622, the ITU 634 and the fabric 400. The PMT 636 is connected to an IPB 638 and to the fabric 400. Therefore, a memory request transaction directed from the cluster 602 targeting for example the memory window or bar 632, the memory-mapped I/O space of the CXL I/O device 148, is routed through the IPB 638 to the PMT 636 and then to the host bridge 622, where it then proceeds through the PPB 626 and the root port 628 to the CXL I/O device 148. An interrupt developed by the ITU 634 is provided to the PMT 636 and routed to the IPB 638 and presented to the fabric 400 to be delivered to the designated interrupt handling device. PCI messages (PMSG) travel between the fabric 400 and the CXL I/O 148 through the IPB 638, PMT 636, host bridge 622, PPB 626, and root port 628. A first partition 640 is contained in the chiplet hub 102 and includes the IPB 638, PMT 636, host bridge 622, ITU 634 and MMU 624. The partition 640 connects to the fabric partition 614. Partition 640 is an example of an expander partition. A second partition 629 includes the PPB 626, root port 628 and the windows to the PPB 626 and CXL I/O 148 resources as defined by bars 630 and 632. The partition 629 is an example of a non-expander partition as it does not perform routing function but only designates devices such as PPB 626 and CXL I/O 148 via RP 628 for routing to and from the devices. Partition 629 connects between the CXL I/O device 148 and the partition 640.

The DRAM 142 is connected to platform independent memory completer (PI-MEMC), effectively a memory controller 644, which is in a non-expander partition 643. The PI-MEMC 644 is the primary element of memory controller chiplet 134. The PI-MEMC 644 is connected to an emulated memory access splitter (EMAS) 646. The EMAS 646 operates to adapt the DRAM 142 to be available in multiple system instances rather than being dedicated to just one system instance, in this case the IHS 1 168 system instance. The EMAS 646 is connected to memory mapper (MM) 647, which is connected to a PMT 648 which is connected to a coherency unit (CHA for coherency home agent) 650 and an IPB 652. The memory transactions addressed to the DRAM 142 are provided through the IPB 652 and then routed by the PMT 648 to the coherency unit 650 to determine if a snoop transaction is necessary. If not, the CHA 650 provides the memory transaction to the PMT 648, which forwards the memory transaction to the EMAS 646 to the PI-MEMC 644 to the DRAM 142. If so, the coherency unit 650 provides a snoop request to the PMT 648, where it is routed through the IPB 652 to the fabric 400 and in this case back through IPB 612 to the cluster 602. The snoop response goes through the IPB 652, to the PMT 648, to the CHA 650, to the EMAS 646, to the PI-MEMC 644 and then to the DRAM 142.

The SRAM 110 and its related elements are located in a partition 654. The SRAM 110 is connected to a PI-MEMC 656, which is connected to an EMAS 658, which is connected to an MM 657, which is connected to a PMT 660. A coherency unit 662 is connected to the PMT 660 and an IPB 664 is connected to the PMT 660 to interconnect with the fabric 400. Memory and snoop transactions flow in the SRAM partition 654 just as they did in the DRAM partition 642. The collection of the partitions 610, 619, 614, 640, 629, 642, 643 and 654 form the IHS 1 168 system instance.

To better explain the operation of the elements in IHS 1 168, two example transactions are explained in detail. The first transaction is a memory transaction from the CXL I/O 148 to the DRAM 142. The second transaction is a memory transaction from the cluster 602 to the SRAM 11. The tables for each PMT and the fabric 400 are provided to illustrate exemplary routing values. Tables are provided for memory transactions (MEM), snoop transactions (SNP) and completion transactions (CMP).

### PMT 606

TABLE 1
PMT 606 MEM

| Routing | | MEM | Cacheable | Coherence | Transaction | Transaction |
|---|---|---|---|---|---|---|
| Rule | Prio | Mappings | MEM | Phase | Source | Destination |
| #1 | 1 | Default | X | X | cluster 602 | IPB 608 |
| | | | | | coreᵢ | |

TABLE 2
PMT 606 SNP

| Routing | | SNP | Transaction | Transaction |
|---|---|---|---|---|
| Rule | Prio | Mappings | Source | Destination |
| #1 | 1 | cluster 602 coreᵢ | IPB 612 | cluster 602 coreᵢ |
| #2 | 2 | Default | IPB 612 | Error |

TABLE 3
PMT 606 CMP

| Routing | | CMP | Transaction | Transaction |
|---|---|---|---|---|
| Rule | Prio | Mappings | Source | Destination |
| #1 | 1 | cluster 602 core | IPB 612 | cluster 602 coreᵢ |
| #2 | 2 | Default | cluster 620 coreᵢ | IPB 608 |
| #3 | | | IPB 618 | Error |

### PMT 636

TABLE 4
PMT 636 MEM

| Routing | | MEM | Transaction | Transaction |
|---|---|---|---|---|
| Rule | Prio | Mappings | Source | Destination |
| #1 | 1 | host bridge 622 | IPB 638 | host bridge 622 |
| #2 | | config space | root port 628 | Error |
| #3 | | PPB 626 bridge | IPB 638 | root port 628 through |
| | | space | | host bridge 622 with |
| | | | | final destination CXL |
| | | | | I/O 148 |
| #4 | | | root port 628 | root port 628 through |
| | | | | host bridge 622 with |
| | | | | final destination CXL |
| | | | | I/O 148 |
| #5 | | BAR-MA 630 | IPB 638 | PPB 626 through host |
| | | | | bridge 622 |
| #6 | | | root port 628 | PPB 626 through host |
| | | | | bridge 622 |
| #7 | 2 | Default | IPB 638 | Error |
| #8 | | | root port 628 | IPB 638 |

TABLE 5
PMT 636 CMP

| Routing | | CMP | Transaction | Transaction |
|---|---|---|---|---|
| Rule | Prio | Mappings | Source | Destination |
| #1 | 1 | PPB 626 | X | Error |
| #2 | | CXL I/O 148 | IPB 638 | root port 628 through |
| | | | | host bridge 622 with final |
| | | | | destination CXL I/O 148 |
| #3 | 2 | Default | IPB 638 | Error |
| #4 | | | root port 628 | IPB 638 with final |
| | | | | destination cluster |
| | | | | 602 coreᵢ |

### PMT 648

TABLE 6
PMT 648 MEM

| Routing | | MEM | Cacheable | Coherence | Transaction | Transaction |
|---|---|---|---|---|---|---|
| Rule | Prio | Mappings | MEM | Phase | Source | Destination |
| #1 | 1 | DRAM 142 | NO | X | IPB 652 | DRAM 142 |
| #2 | | mapped address | YES | PRE | IPB 652 | CHA 650 |
| #3 | | | YES | POST | CHA 650 | DRAM 142 |
| #4 | 2 | Default | X | X | IPB 652 | Error |

TABLE 7
PMT 648 SNP

| Routing | | SNP | Transaction | Transaction |
|---|---|---|---|---|
| Rule | Prio | Mappings | Source | Destination |
| #1 | 1 | Default | CHA 650 | IPB 652 |

TABLE 8
PMT 648 CMP

| Routing | | CMP | Transaction | Transaction |
|---|---|---|---|---|
| Rule | Prio | Mappings | Source | Destination |
| #1 | 1 | CHA 650 | IPB 652 | CHA 650 |
| #2 | 2 | Default | IPB 652 | Error |
| #3 | | | DRAM 142 | IPB 652 |

### PMT 660

TABLE 9
PMT 660 MEM

| Routing | | MEM | Cacheable | Coherence | Transaction | Transaction |
|---|---|---|---|---|---|---|
| Rule | Prio | Mappings | MEM | Phase | Source | Destination |
| #1 | 1 | SRAM 110 | NO | X | IPB 664 | SRAM 110 |
| #2 | | mapped address | YES | PRE | IPB 664 | CHA 662 |
| #3 | | | YES | POST | CHA 662 | SRAM 110 |
| #4 | 2 | Default | X | X | IPB 664 | Error |

TABLE 10
PMT 660 SNP

| Routing | | SNP | Transaction | Transaction |
|---|---|---|---|---|
| Rule | Prio | Mappings | Source | Destination |
| #1 | 1 | Default | CHA 662 | IPB 664 |

TABLE 11
PMT 660 CMP

| Routing | | CMP | Transaction | Transaction |
|---|---|---|---|---|
| Rule | Prio | Mappings | Source | Destination |
| #1 | 1 | CHA 662 | IPB 664 | CHA 662 |
| #2 | 2 | Default | IPB 664 | Error |
| #3 | | | SRAM 110 | IPB 664 |

TABLE 12
Fabric 400 MEM

| Routing | | MEM | Transaction | Transaction |
|---|---|---|---|---|
| Rule | Prio | Mappings | Source | Destination |
| #1 | 1 | IPB 638, | IPB 638, 652, | different of IPB |
| | | 652, 664 | 664 | 638, 652, 664 |
| #2 | | | IPB 608 | IPB 638, 652, 664 |
| #3 | 2 | Default | X | Error |

TABLE 13
Fabric 400 SNP

| Routing | | SNP | Transaction | Transaction |
|---|---|---|---|---|
| Rule | Prio | Mappings | Source | Destination |
| #1 | 1 | IPB 612 | IPB 638, 652, 664 | IPB 612 |
| #2 | 2 | Default | X | Error |

TABLE 14
Fabric 400 CMP

| Routing | | CMP | Transaction | Transaction |
|---|---|---|---|---|
| Rule | Prio | Mappings | Source | Destination |
| #1 | 1 | IPB 612 | IPB 638, 652, | IPB 612 |
| | | | 664 | |
| #2 | | IPB 618, 638, | IPB 638, 652, | different of IPB |
| | | 652, 664 | 664 | 638, 652, 664 |
| #3 | | | IPB 608 | IPB 638, 652, 664 |
| #4 | 2 | Default | X | Error |

### Flow Walkthrough

### CXL I/O 148 to DRAM 142

This flow is initiated by CXL I/O 148 reading from (or writing to) the target memory, in this case DRAM 142. For the below walkthrough, a read from non-cacheable memory is assumed.

1. CXL I/O 148 issues a PCIe US memory read transaction (MRdAddr=0x1234 5678 1000).

2. PPB 626 receives the memory read transaction via RP 628, processes it and forwards the transaction to host bridge 622.

3. Host bridge 622 first forwards the memory transaction to MMU 624 to translate the untranslated memory address (0x1234 5678 1000) into an IHS 1 168 system physical address (SPA=0x1000 1000). Then the transaction (with SPA) is delivered to the fabric 400.

4. The fabric 400 routes the memory transaction based on PMT MEM tables in the following order:

1. PMT 636 MEM table (Table 4): routing rule #8 gets executed. The MEM transaction is forwarded to IPB 638.

2. Fabric 400 MEM table (Table 12): routing rule #1 gets executed. The MEM transaction is forwarded to IPB 652.

3. PMT 648 MEM table (Table 6): routing rule #1 gets executed. The MEM transaction targets non-cacheable memory and is forwarded to DRAM 142 directly.

5. DRAM 142 receives the memory transaction, reads DRAM 142 and issues the completion to the fabric 400.

6. The fabric 400 routes the memory CMP based on PMT CMP tables in the following order:
1. PMT 648 CMP table (Table 8): routing rule #3 gets executed. The CMP is forwarded to IPB 652.
2. Fabric 400 CMP table (Table 14): routing rule #2 gets executed. The CMP transaction is forwarded to IPB 638.
3. PMT 636 CMP table (Table 5): routing rule #2 gets executed. The CMP transaction is forwarded through host bridge 622 to RP 628.

7. The RP 628 forwards the completion to CXL I/O 148.

### Cluster 602 Core 9 to SRAM 110

This flow is initiated by cluster 602 core 9, reading from (or writing to) the target memory, in this case SRAM 110. For the below walkthrough, a write to cacheable memory is assumed.

1. Cluster 602 core 9 issues a memory write transaction (Addr=0x9000 0080) to PMT 606.

2. The memory transaction is routed first by an external fabric (not explicitly shown) inside Internal Compute 1 chiplet 122, based on PMT 606 MEM table (Table 1): routing rule #1 gets executed. The MEM transaction is forwarded to IPB 608 and then from IPB 608 to chiplet hub 102 across the D2D link.

Fabric 400 receives the memory transaction from IPB 608 and routes it based on PMT MEM tables in the following order:
1. Fabric 400 MEM table (Table 12): routing rule #2 gets executed. The MEM transaction is forwarded to IPB 664.
2. PMT 660 MEM table (Table 9): routing rule #2 gets executed. The MEM transaction targets cacheable memory and is forwarded to CHA 662 first to resolve coherence.
3. CHA 662 performs directory lookup and determines that cluster 602 core 12 needs to be snooped to resolve coherence. CHA 662 issues a snoop transaction (with DestinationID=cluster 602 core 12) to the fabric 400.
4. The snoop transaction is routed based on PMT SNP tables in the following order:
   1. PMT 660 SNP table (Table 10): routing rule #1 gets executed. The SNP transaction is forwarded to IPB 664.
   2. Fabric 400 SNP table (Table 13): routing rule #1 gets executed. The SNP transaction is forwarded to IPB 612.
   3. PMT 606 SNP table (Table 2): routing rule #1 gets executed. The SNP transaction is forwarded to cluster 602 core 12.
5. Cluster 602 core 12 receives the snoop transaction, processes it and sends back a SNP completion (i.e. CMP).
6. The snoop completion is routed based on PMT CMP tables in the following order:
   1. PMT 606 CMP table (Table 3): routing rule #2 gets executed. The CMP transaction is forwarded to IPB 608.
   2. Fabric 400 CMP table (Table 14): routing rule #3 gets executed. The CMP transaction is forwarded to IPB 664.
   3. PMT 660 CMP table (Table 11): routing rule #1 gets executed. The CMP transaction is forwarded to CHA 662.
7. CHA 662 processes the snoop response and issues the post-coherence-resolution memory transaction to the fabric 400.
8. The post-coherence-resolution MEM transaction is routed based on PMT 660 MEM table (Table 9): routing rule #3 gets executed. The MEM transaction is forwarded to SRAM 110.
9. SRAM 110 receives the memory transaction, writes the data to the SRAM 110 and issues the completion to the fabric 400.
10. The memory CMP is routed based on PMT CMP tables in the following order:
   1. PMT 660 CMP table (Table 11): routing rule #3 gets executed. The CMP is forwarded to IPB 664.
   2. Fabric 400 CMP table (Table 14): routing rule #1 gets executed. The CMP transaction is forwarded to IPB 612.
   3. PMT 606 CMP table (Table 3): routing rule #1 gets executed. The CMP transaction is forwarded to cluster 602 core 9.

As mentioned, fabric 400 only handles routing based on PMTs within the chiplet hub 102. However, to complete the picture of IHS 1 168, PMTs contained in the internal compute 1 112 chiplet, such as PMT 606 and PMT 616, are also shown and described. It is understood that the chiplet, such as internal compute 1 122, must perform the routing functions of those PMTs with its internal fabric.

Referring to FIG. 3 and FIG. 6A2, a variant of IHS 1 168 system instance is provided referred to as IHS 1′ 168′ system instance. IHS 1′ 168′ system instance includes an accelerator 3 126 in the IHS 1 168 system instance. This is illustrated in detail in FIG. 6A2. The accelerator 3 126 includes a platform independent hosted accelerator (PIHA) 666, contained in a non-expander partition 667, which is connected to a non-expander partition 668 and then to the fabric 400. The PIHA 666 is connected to an emulated native downstream device (ENDD) 670, to adapt the independent nature of the PIHA 666 to the native operation of the IHS 1′ 168′ system instance supported by chiplet hub 102. Native refers to the addressing, interrupts, messaging, MMU, coherence protocols, memory attributes and the like for an architecture decided to be the basic architecture of the system instance, which must be one of the basic architectures supported by the chiplet hub 102. In one embodiment, the ARM architecture is the basic architecture of the chiplet hub 102 and its supported system instances such as IHS 1′ 168′, so operations according to the ARM architecture are native operations. Independent is then any architecture other than ARM, such as RISC-V, x86, Power, and so on which requires conversions to work with the ARM architecture. The ENDD 670 is connected to an MMU 672 and is connected to a PTSB 674. The PTSB 674 is connected to the fabric 400. As described in more detail below the MMU 672 provides a conversion from the address space of the accelerator 3 126 to the physical address space of the relevant system instance, in this case IHS 1′ 168′. Memory transactions are received at the PTSB 674 from the MMU 672. Memory transactions are provided from PTSB 674 to MM 671 and then to ENDD 670. Snoop requests are provided from the PTSB 674 to the ENDD 670. Messages are exchanged between the ENDD 670 and the PTSB 674. Interrupts are passed from the ENDD 670 to the PTSB 674. Each system instance has its own physical address space. Memory transactions refer to partition instances and physical addresses for that particular instance. The physical addresses for the system instance are converted by a memory mapper associated with a memory device.

If PIHA 666 had instead been a platform native hosted accelerator (PNNA), the ENDD 670 would not be needed and the PNNA could connect directly to the MMU for outbound memory transactions and to the PTSB for other type of transactions and then to the fabric 400.

FIG. 6B illustrates the details relating to IHS 2 170. IHS 2 170 connects the internal compute 2 124 to the I/O 130, CXL I/O 148, CXL HDM 150, I/O and load and store 128, CXL HDM 146 and the DRAM 142. An IPB 1602 is connected to the fabric 400 and passes memory and PCI message to a PMT 1604 and receives interrupt transactions from the PMT 1604. The IPB 1602 and PMT 1604 relate to the connection to the CXL I/O 148 and are part of partition 1601. A host bridge 1623 is connected to the PMT 1604. An ITU 1635 is connected to the host bridge 1623 and provides interrupt to the PMT 1604. An MMU 1625 is connected to host bridge 1623 to translate addresses. Noting that the IHS 1 168 is also connected to the CXL I/O 148, therefore, I/O 130 and CXL I/O 148 are shared between the system instances IHS 1 168 and IHS 2 170. It is understood that for a PCI/CXL device to be shared, the PCI/CXL device must be able to be bifurcated. For this description, it is assumed that I/O 130 and CXL I/O 148 can bifurcate as needed. Each bifurcated device is independent. This is illustrated in FIG. 6B by the use of distinct element numbers for the PPB 1680 and root port 1682 in the I/O 130. BARs 1629 and 1631 are also different from the BARS 630, 632 in IHS 1 168, as different addresses are used with the different system instances. The PMT 1604 cannot be shared with the PMT 606 because the routing is different based on the particular system instance, in this case the IHS 2 170 system instance. Similarly, the IPB 1602 cannot be shared as that is the entry from the fabric 400 for the use of the CXL I/O 148 by the IHS 2 170 system instance. The host bridge 1623 and MMU 1625 cannot be shared because of the differing address spaces between IHS 1 168 and IHS 2 170.

The EMAS 646, the PI-MEMC 644 and the DRAM 142 are shared between IHS 1 168 and IHS 2 170. IHS 2 170 has a different PMT 1606 connected to the MM 1607 connected to the EMAS 646. PMT 1606 is connected to a coherency unit 1608 and to an IPB 1610. The IPB 1610 is connected to the fabric 400. Memory transactions are provided to the IPB 1610 from the fabric 400 and snoop transactions are passed from the IPB 1610 to the fabric 400. Memory transactions are exchanged between the CHA 1608 and the PMT 1606. Snoop transactions are provided from the CHA 1608 to the PMT 1606. Memory transactions are provided from the PMT 1606 to the EMAS 646 for provision to the DRAM 142.

Internal compute 2 124 includes a cluster 1612 for performing transactions. The cluster 1612 provides memory transactions to a PMT 1616 and receives snoop transactions from the PMT 1616. PMT 1616 is connected to an IPB 1618, which is connected to the fabric 400. The PMT 1616 exchanges memory transactions with the IPB 1618. The PMT 1616 receives snoop transactions from an IPB 1620 connected to the fabric 400. Interrupt transactions are provided from fabric 400 to an IPB 1622, which connects to a PMT 1624 for routing purposes. An interrupt distribution controller (IDC) 1626 is connected to the PMT 1624. The PMT 1624 allows any interrupts to be distributed as determined by the IDC 1626 among the particular cores in the cluster 1612.

CXL HDM 146 is illustrated as being configured for use by a single host rather than shared by a number of hosts and accelerators. The interface between the fabric 400 and the CXL HDM 146 includes two partitions, partition 1630 which is connected to the fabric 400 and partition 1632 which is connected to the CXL HDM 146. The partition 1630 includes an IPB 1632 connected to the fabric which exchanges memory and snoop transactions and provides interrupts to the fabric 400. The IPB 1632 is connected to a PMT 1634 which is also connected to a coherency unit 1636. The coherency unit 1636 exchanges memory transactions with the PMT 1634 and provides snoop transactions to the PMT 1634. The PMT 1634 is connected to a host bridge 1638 and receives interrupts from an interrupt translation unit 1640, which translates any received PCI interrupts into native interrupts. An MMU 1642 is connected to the host bridge 1638 to translate addresses of PCI interrupt vectors as needed by the fabric 400. The host bridge 1638 is connected into the second partition 1631. The second partition 1631 includes a PCI-to-PCI and load store outbound bridge 1644. The bridge 1644 is connected to the host bridge 1638. A root port 1646 is provided by the PCI-to-PCI and load store bridge 1644. The root port 1646 is connected to the CXL HDM 146. A memory window or BAR 1648 appears at the PCI-to-PCI and load store bridge 1644, while a BAR or address window 1650 is presented to the CXL HDM 146 to allow memory-mapped I/O transactions.

CXL HDM 150 is shared by numerous hosts and accelerators from multiple distinct system instances and therefore the interface to the fabric 400 is configured differently than the interface for CXL HDM 146. A partition 1652 includes an IPB 1654 which is connected to the fabric 400 and exchanges memory and snoop transactions with the fabric. The IPB 1654 is connected to a PMT 1656, which exchanges memory transactions with a coherency unit 1659 and receives snoop transactions from the coherency unit 1659. The PMT 1656 is also connected to an MM 1657 for memory mapping and to an EMAS 1658 to allow splitting memory transactions among hosts and accelerators and a memory exporter unidirectional bridge (MEUB) 1660. Partition 1652 ends after the EMAS 1658. The MEUB 1660 is a bridge between an external fabric and a system instance, in this case the IHS 2 170 system instance. A partition 1673 starts at the MEUB 1660. The MEUB 1660 is connected to the upstream port of a memory controller interface (USP-MEMC) 1662. To allow sharing of the CXL HDM 150 and any other similarly connected CXL HDMs as a pool by the various other devices, an internal fabric 1664 is provided so that each of the other relevant devices can have an interface into the fabric and the various transactions can be transferred from the CXL HDM 150 and any other CXL HDMs as needed to the appropriate device. For use with IHS 2 170, a PMT 1665 is connected to an IPB 1666, which is connected to the upstream port memory controller 1662 and to a fabric 1668. In one embodiment the fabric 1668 is itself an EHS system instance using the fabric 400, with each system instance sharing the CXL HDM 150 and the CXL HDM 150 itself acting as the devices connected to the fabric 400 for the EHS instance, hence the IPBs 1666 and 1670 connecting to the fabric 1668. An EHS instance is described below. An IPB 1670 is connected to the fabric 1668 and to a PMT 1671, which is connected to a downstream port of a PCI-to-PCI and load store bridge 1672. Partition 1673 ends with the PCI-to-PCI and load store bridge 1672. The PCI-to-PCI and load store bridge 1672 is connected to the CXL HDM 150 using conventional CXL/PCIe semantics. This configuration of the CXL HDM 150 provides the capability to share a single CXL HDM device between multiple hosts and accelerators that are not CXL-aware and allows sharing multiple CXL HDMs, but does come with the drawback that a D2D link as described below cannot be utilized.

The NHS 1 164 system instance is illustrated in FIG. 6C. NHS 1 164 interconnects accelerator 1 118, accelerator 2 120, HBM DRAM 116, DRAM 140 and SRAM 11. Accelerator 1 118 includes a cluster 2602 of non-hosted accelerator agents. The cluster 2602 can be formed of whatever of the various devices are desired to be used for accelerator 1 118. Exemplary devices include graphical processing units (GPUs), network processing units (NPUs), custom function ASICs and FPGAs and any other desired accelerator device or unit. The cluster 2602 provides memory transactions to an MMU 2606 connected to the PMT 2604. As accelerator 1 118 contains memory 138, it is illustrated as having a portion of the memory 138 available as system memory. This is illustrated in FIG. 6C as NHS allocated memory 2068. The NHS allocated memory 2608 is connected to the PMT 2604. A coherency unit 2610 is connected to the PMT 2604 to provide snoop transactions and exchange memory transactions. An IPB 2612 connects the PMT 2604 to the fabric 400. The PMT 2604 is used to route the memory transactions from the cluster 2602 to fabric 400, the NHS allocated memory 2608 or to the coherency unit 2610 as necessary. The PMT 2604 will route external memory requests such as from accelerator 2 120 to the NHS allocated memory 2608. A memory transaction from accelerator 2 120 reaches the fabric 400 and reaches IPB 2612 and then is provided to PMT 2604 to be routed to the memory 2608. These functions are contained in a partition 2614. Accelerator 1 118 includes a second partition 2616 which includes an IPB 2618 connected to the fabric 400 and a PMT 2620 connected to the cluster 2602. The IPB 1618 exchanges messages with the fabric 400 and the PMT 2620. The PMT 2620 routes the messages to the appropriate of the individual units in the cluster 2602.

Accelerator 2 120 includes a platform independent non-hosted accelerator (PINA) 2622 and a cluster 2624 of non-hosted agents. These are the acceleration elements in the accelerator 2 120. The PINA 2622 is connected to a partition 2626, which includes an emulated native non-hosted agent (ENNA) 2628 to interface the independent transactions to native transactions and to exchange transactions with the PINA 2622. An MMU 2630 is connected to the ENNA 2628 to update addresses being received from the PINA 2622. The MMU 2630 is connected to a PTSB 2632, which is connected to the fabric 400. The MMU 2630 provides memory transactions to the PTSB 2632. The PTSB 2632 provides snoop transactions to the ENNA 2628 and memory transactions to an MM 2631, which forwards the memory transaction to ENNA 2628.

The cluster 2624 is connected to a partition 2634 which includes a PMT 2636 and an IPB 2638. The IPB 2638 exchanges messages with the fabric 400. The PMT 2636 routes messages between the individual devices in the cluster 2624 and the IPB 2638.

The HBM DRAM 116 is illustrated as a portion of NHS 1 164. A partition 2640 includes an IPB 2642 which receives memory transactions from and provides snoop transactions to the fabric 400. The IPB 2642 is connected to a PMT 2644 for routing purposes. A coherency unit 2646 is connected to the PMT 2644 to perform the coherency checking. An MM 2647 receives memory transactions from the PMT 2644 and provides them to an EMAS 2648 and then to a memory controller 2650, which is connected to the HBM DRAM 116.

As discussed above, because the DRAM 140 is shared among various devices, a partition 2652 contains the DRAM 140, the PI-MEMC 643 and the EMAS 645. The EMAS 645 is connected to an MM 2653, which is connected to a PMT 2654, which provides memory transactions to the EMAS 645. A coherency unit 2658 is connected to the PMT 2654. An IPB 2660 provides snoop transactions to the fabric 400 and receives memory transactions from the fabric 400, which are then passed to the PMT 2654 for operation.

In similar manner, SRAM 110 is shared. SRAM 110 is in a partition 2662 which includes the SRAM 110, the PI-MEMC 656 and the EMAS 658. A PMT 2664 is connected to an MM 2663, which is connected to the EMAS 658. The PMT 2664 is connected to an IPB 2666, which receives memory transactions from the fabric 400 and provides snoop transactions to the fabric 400. A coherency unit 2668 is connected to the PMT 2664.

NHS 2 166 is illustrated in FIG. 6D. NHS 2 166 connects two independent PINA agents 3601 and 3642 of the embedded accelerator 104 to the DRAM 140, the HBM DRAM 116, and the CXL HDM 150. A first PINA agent 3601 is located in a partition 3602 which includes an ENNA 3604 to translate transactions. The ENNA 3604 includes an MMU 3606 which is connected to a PTSB 3608. Memory transactions are provided from the PINA agent 3601 to the ENNA 3604 to the MMU 3606 to the PTSB 3608 and then to the fabric 400. Memory and snoop transactions are received from the fabric 400 through the PTSB 3608 to the ENNA 3604, the memory transactions passing through MM 3605. The second PINA agent 3642 is connected to an ENNA 3644. The ENNA 3644 includes an MMU 3646 which is connected to a PTSB 3648. Memory transactions are provided from the PINA agent 3642 to the ENNA 3644 to the MMU 3646 to the PTSB 3648 and then to the fabric 400. Memory and snoop transactions are received from the fabric 400 through the PTSB 3648 to the ENNA 3644, the memory transactions passing through MM 3645. Messages are passed between the fabric 400 and an IPB 3610 and a PMT 3611. The PMT 3611 is connected to ENNA 3604 and ENNA 3644 to route messages from the fabric 400 to the proper of PINA agent 3601 and PINA agent 3642. Messages from PINA agents 3601 and 3642 pass through the PMT 3611 to the IPB 3610 to the fabric 400.

For use by the NHS 2 166, two partitions 3612 and 1673 are associated with the CXL HDM 150. The partition 3612 includes an IPB 3614 connected to the fabric 400. Memory transactions and snoop transactions are provided through the IPB 3614. The IPB 3614 is connected to a PMT 3616 which is also connected to a coherency unit 3618. The MM 3611 is connected to PMT 3616 for memory mapping. The EMAS 1658 is connected to the MM 3611 to allow splitting of memory transactions. The EMAS 1658 and all components below the EMAS 1658 are shared with any other system instances accessing the CXL HDM 150. Partition 3612 ends after the EMAS 1658 and partition 1673 begins. The MEUB 1660 is connected to the EMAS 3620 and to the upstream port of the memory controller 1662. Memory controller 1662 is connected to the PMT 1665, which is connected to the IPB 1666 which in turn is connected to the fabric 1668 which allows sharing of the CXL HDM 150.

A partition 3628 is utilized with the HBM DRAM 116. An IPB 3630 receives memory transactions from the fabric 400 and provides snoop transactions to the fabric 400. The IPB 3630 is connected to a PMT 3632, which is connected to a coherency unit 3635. The PMT 3632 is connected to the MM 3633 and the EMAS 2648 to allow memory transactions to proceed to the HBM DRAM 116.

A partition 3634 is utilized with the DRAM 140. The partition 3634 includes an IPB 3636 connected to the fabric 400 to receive memory transactions and provide snoop transactions. The IPB 3636 is connected to a PMT 3638. A coherency unit 3641 is connected to the PMT 3638. In this embodiment, the DRAM 140 is utilized with two different memory controllers, one that is independent, PI-MEMC 644, and one that is native, PN-MEMC 3640. For transactions addressed to the memory space assigned for the PI-MEMC 644, memory transactions are provided by the PMT 3638 to the MM 3637 to the EMAS 645. For memory transactions directed to the memory space assigned for the PN-MEMC 3640, the PMT 3638 provides those memory transactions to a MM 3643, which are then forwarded to the PN-MEMC 3640, which operates with the DRAM 140.

EHS 172 is illustrated in FIG. 6E. EHS 172 includes the external compute 144, accelerator 2 120, DRAM 142 and CXL HDM 150. The external compute 144 is connected to a PCI root complex or CXL switch 146 external to the SiP 100 and connected to I/O and load/store chiplet 136 in the SiP 100. A partition 4602 contains the I/O and load and store chiplet 136. The PCI root complex or CXL switch 146 is connected to an upstream port 4604 of a PCI-to-PCI and load and store bridge 4606 using a CXL link. The PCI-to-PCI and load and store bridge 4606 provides a memory window or BAR 4608, in this case an upstream bar. The PCI-to-PCI and load and store bridge 4606 is connected to the fabric 400. Memory transactions and PCI messages are exchanged between the bridge 4606 and a PTSB 4607. The memory transaction and PCI messages are exchanged between the PTSB 4607 and the fabric 400 and PCI configuration messages are provided from the bridge 4606 to the PTSB 4607 and then to the bridge 4606. The PCI configuration messages are used to configure any downstream connected PCI devices.

Accelerator 2 120 contains a platform independent hosted accelerator (PIHA) 4611 that is connected to a partition 4610 which contains an emulated CXL/PCI endpoint (ECEP) 4612. The ECEP 4612 emulates a PCI endpoint to the external host, the external compute 144. The ECEP 4612 provides a memory window or BAR 4614 for addressing by the PIHA 4611. The ECEP 4612 is connected to the downstream port 4616 of a PCI-to-PCI bridge 4618. The PCI-to-PCI bridge 4618 presents a window or BAR 4620 for the external compute 144 to access the address space of the PIHA 4611. It is noted that the PCI-to-PCI bridge 4618 and downstream port 4616 are emulated in this case. In the case of PCI-to-PCI bridge 1644, which was a physical bridge as it was on a chiplet, PCI-to-PCI bridge 4618 and downstream port 4616 are on the chiplet hub 102 and related to the emulated ECEP 4612, so PCI-to-PCI bridge 4618 and downstream port 4616 are also emulated. A PMT 4622 is connected to the PCI-to-PCI bridge 4618. An IPB 4624 is connected to the PMT 4622 and to the fabric 400. Memory transactions and PCI messages are exchanged between the fabric 400 and the IPB 4624. The memory transactions received from the fabric 400 will be directed to either the BAR-MA portion of BAR 4614 or BAR-MA portion of BAR 4620 and the memory transactions provided to the fabric 400 will be provided by the PIHA 4611.

A partition 4626 is utilized with the DRAM 142 and includes an IPB 4628 to receive memory transactions from the fabric 400 and provide those transactions to a PMT 4630, which provides those transactions to the MM 4631 and the EMAS 646.

A partition 4632 is used with the CXL HDM 150 in EHS 172 and includes an IPB 4634 connected to the fabric 400 and receives memory transactions. The IPB 4634 is connected to a PMT 4636, which is also connected to the MM 4637, which is connected to the EMAS 1658, which is connected to an MEUB 1660. The partition 4632 stops after the EMAS 1658. The MEUB 1660 is connected to memory controller 1662, which in turn is connected to PMT 1665, which in turn is connected to IPB 1666. The IPB 1666 connects to the shared fabric 1668 used for the CXL HDM 150.

Partition 4626 and partition 4632 provide the memory for upstream switch memory buffer (USMB) of BAR 4608, downstream switch memory buffer (DSMB) of BAR 4620, and accelerator memory buffer (AMB) of BAR 4614. AMB can be used by PIHA 120 as device memory for PCI peer-to-peer memory transactions. DSMB can be used by all devices downstream from the DSP 4616 as shared and explicitly coherent memory. USMB can be used by all devices downstream from the USP 4604 as shared and explicitly coherent memory.

FIG. 6F illustrates PMS 162. Accelerator 1 118 includes platform-independent private memory accessor (PIPA) 5601. Any accelerator or compute unit can be a private memory accessor, so the generic form of PIPA is used. The PIPA 5601 is connected to a partition 5602 in the chiplet hub 102. The PIPA 5601 connects to an emulated native private memory accessor (ENPA) 5604 in the partition 5602. The ENPA 5604 emulates the necessary platform-native requester agent to the PIPA 5601 and a native memory accessing device to the fabric 400. The ENPA 5604 is connected to an MMU 5606 to translate memory addresses which are provided from the PIPA 5601 address space to the private address space of the PMS 162. The MMU 5606 is connected to and provides memory transactions to a PTSB 5608, which is connected to the fabric 400. Memory transactions proceed from the PIPA 5601 to the ENPA 5604 to the MMU 5606 to the PTSB 5608 to the fabric 400. Memory transactions provided from the fabric 400 go to the PTSB 5608, to an MM 5605 and then to the PIPA 5601. An MM 5605 receives memory transactions from the PTSB 5608 and provides them to the PIPA 5601.

An IPB 5610 is connected to the fabric 400 and to a PMT 5612. The PMT 5612 is connected to the MM 5613 and the EMAS 645 of the DRAM 140. The IPB 5610, PMT 5612, MM 5613 and EMAS 645 are in a partition 5609.

The SRAM 110 and its related elements are located in a partition 5614. The SRAM 110 is connected to a PI-MEMC 656, which is connected to an EMAS 658, which is connected to an MM 5617, which is connected to a PMT 5616. An IPB 5620 is connected to the PMT 5616 to interconnect with the fabric 400.

FIG. 6G1 illustrates the sharing of memory devices by system instances. SRAM 110 is the first illustrated memory and the related system instances are IHS 1 168, NHS 1 164 and PMS 162. DRAM 142 is the second illustrated memory and the related system instances are IHS 1 168, IHS 2 170 and EHS 172. Referring to SRAM 110, the dashed lines representing partitions 654, 2662 and 5614 are illustrated as covering SRAM 11. This illustrates the memory address separation of the IHS 1 168, NHS 1 164 and PMS 162 system instances.

FIG. 6G2 illustrates the sharing of an accelerator. Accelerator 1 118 and the NHS 1 164 and PMS 162 system instances are shown. The PIPA 5601 is shown as one of the agents in the cluster 2602.

This completes the detailed description of the various examples of independent system instances which may be present in the chiplet hub 102. Various compute devices, such as ARM or RISC-V CPUs, can be used. As mentioned above, many different types of accelerators, either programmable or dedicated function, can be used. Memory is provided in a full hierarchy, from SRAM to HBM DRAM to DRAM to CXL HDM to CXL- or PCIe-connected external I/O devices acting as persistent memory, and configured in multiple ways. The chiplet hub 102 provides adapters and various services, such as IPBs, CHAs and MMUs, as needed to allow the compute and accelerator devices to communicate with each other with both message passing and shared memory models.

As discussed above, this has been a detailed description of exemplary system instances in an exemplary combination of system instances to assist in understanding operation of the system. Any desired number or combination of system instances and system instance types can be implemented as needed.

FIG. 6H illustrates the CCS 160. The CCS 160 represents the chassis level interconnect of the SiP 100. All system configuration operations and other selected activities are managed through the chassis via the CCS 160, except that certain PCI host configuration operations, which are performed as memory writes to PCI config space, are handled using the fabric 400. The hub manager 108 is connected to a chassis fabric 6602, which is a different fabric than the fabric 400 in the illustrated embodiment.

FIG. 6H illustrates the various elements in the system 98 which must be initialized and configured for operation. The accelerator 1 118 includes a PHY 6604 which is connected to a companion PHY 6606 of a D2D link. Exemplary D2D links are described below. The PHY 6606 is connected to a link services block 6608 which is connected to the chassis fabric 6602. Accelerator 2 120 includes a PHY 6610 connected to a companion PHY 6612 and its link services block 6614. Internal compute 1 122 includes a PHY 6616 connected to its companion PHY 6620 and the link services block 6622. Internal compute 2 124 includes a PHY 6624 connected to PHY 6626 and its link services block 6628. Accelerator 3 126 includes a PHY 6630 connected to PHY 6632 and its link services block 6634. HDMA controller 106 is directly connected to the chassis fabric 6602, as is the embedded accelerator 104. The I/O and load and store chiplet 128 for the CXL HDM 146 is connected to a PHY 6636, which is connected to a companion PHY 6638 and link services block 6640. CXL I/O 148 is connected to I/O 130 which has PHY 6642 connected to PHY 6644 and link services block 6646. The I/O and load and store chiplet 136 for external compute 144 includes a PHY 6648 which is connected to PHY 6650 and link services block 6652. SRAM 110 is connected directly to the chassis fabric 6602. The PCI-to-PCI and load store bridge 1672 for the CXL HDM 150 is connected to the chassis fabric 6602 to allow configuration messages to be transferred. The CXL link connecting the I/O and load and store bridge 1672 to the CXL HDM 150 is not shown, as the CXL link is not programmed by the hub manager 108. Memory controller 134 is connected to a PHY 6654 which is connected to its complementary PHY 6656 and link services block 6658. An HBM memory controller 114 is connected to the chassis fabric 6602. A vendor buffer/HBM PHY 6660 is connected to the chassis fabric 6602. Operation of the vendor buffer/HBM PHY 6660 is described below.

The system 98 includes a pool of various agent adapters and service providers which are utilized as necessary to provide the functions and emulation capabilities to connect the various devices through the fabric 400. These agent adapters and services are managed through the use of the CCS 160 in the chassis fabric 6602. An agent adapter pool is illustrated as 6662 and includes various emulated adapters ENDD 6664, ECEP 6666, ENMC 6668, ENPA 6670, EMAS 6672 and ENNA 6674. An ENDD or Emulated Native Downstream Device emulates a downstream native device and converts between a platform independent hosted accelerator and native memory and messaging. An ECEP or Emulated CXL EndPoint emulates a CXL/PCI endpoint and converts memory and messages between CXL/PCI and native. An ENMC or Emulated Native Message Completer provides native message completer services and converts to the attached device's message format. An ENPA emulates a platform-native private memory accessor for PMS system instances and converts between independently addressed accelerator and native memory and messaging. An ENNA emulates a platform-native non-hosted agent for NHS system instances and converts between platform independent non-hosted accelerator and native memory and messaging.

The internal service provider pool is illustrated as 6676 and includes various service providers such as PTSB 6681, USP-MEMC 6683, coherency block or CHA 6678, MEUB 6680, ITU 6682, IPB 6684, host bridge (HB) 6686, CSW-CAP 6688 and MPSC 6690, root port emulation (RP-EMU) 6692, downstream port emulation (DSP-EMU) 6694, memory mapping (MM) 6696, MMU 6698, MTSC 6665, CSDC 6687, SATB 6689, and SMAB 6691. CAP for CXL/PCI Switch Capability provides necessary services related to a CXL/PCI switch and CAP for RC Capability provides necessary services related to a root complex. MPSC or Message Passing Service Controller 6690 provides message passing services, such as dependency resolution, deadline delivery and multicasting services. Root port emulation 6692 emulates the root port PCI-to-PCI bridges that connect to emulated CXL/PCI endpoints in IHS instances. Downstream port emulation emulates the downstream port PCI-to-PCI bridges that connect to emulated CXL/PCI endpoints in EHS instances. USP-MEMC 6683 emulates the upstream port of an HDM-Switch and exports the allocations of HDMs associated with the HDM-Switch as a generic memory partition (MEMC), which can be allocated to distinct system instances. MEUB 6680 provides hub manager with the ownership of CXL-HDM and allows other system instances to access the exported memory partitions (USP-MEMC).

The agents and service providers can be any desired combination of hardware, software or combination of hardware and software as appropriate to provide desired performance levels. The agents and service providers can be mapped into pipelines as needed by configuring the routing of transactions to form desired protocol adapters and functions.

While the above discussion has focused on the operation of a single chiplet hub 102, in the preferred embodiment multiple chiplet hubs can be combined to come to develop a clustered chiplet hub or CCH. A PHY 6699 and its companion link services block 6697 are connected to the chassis fabric 6602. The PHY 6699 is connected to a PHY 6695 in a child chiplet hub 6693. The link services block 6691 is connected to the PHY 6695. A chassis fabric 6689 of the child chiplet hub 6693 is connected to the link services block 6691. In this manner, configuration and management operations between the two chiplet hubs 102 and 6693 can be developed.

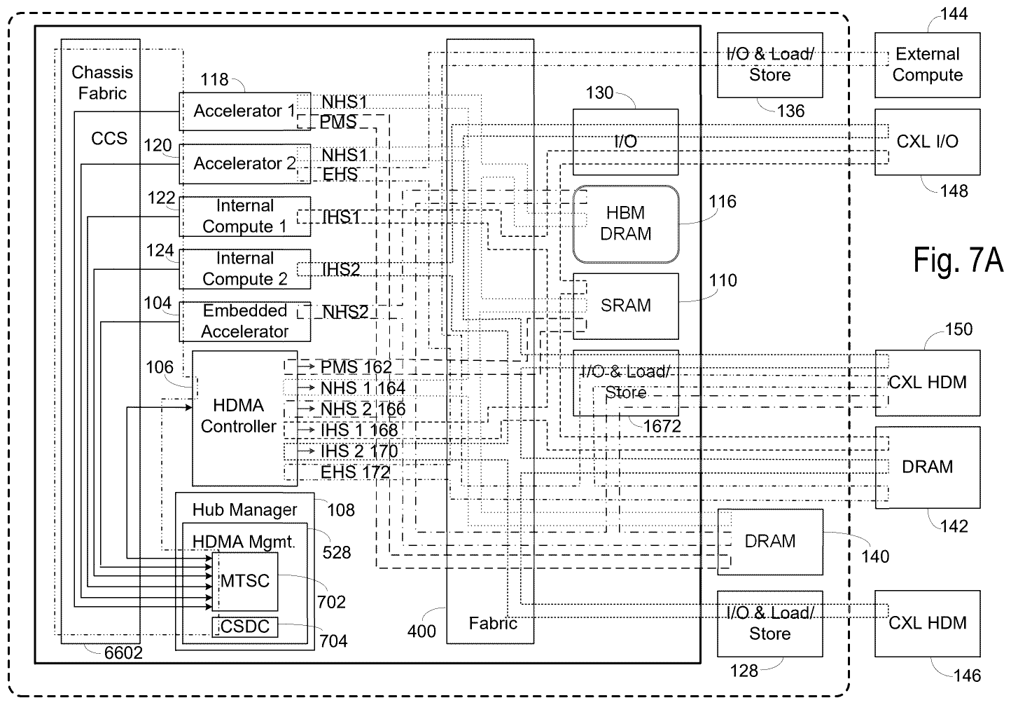

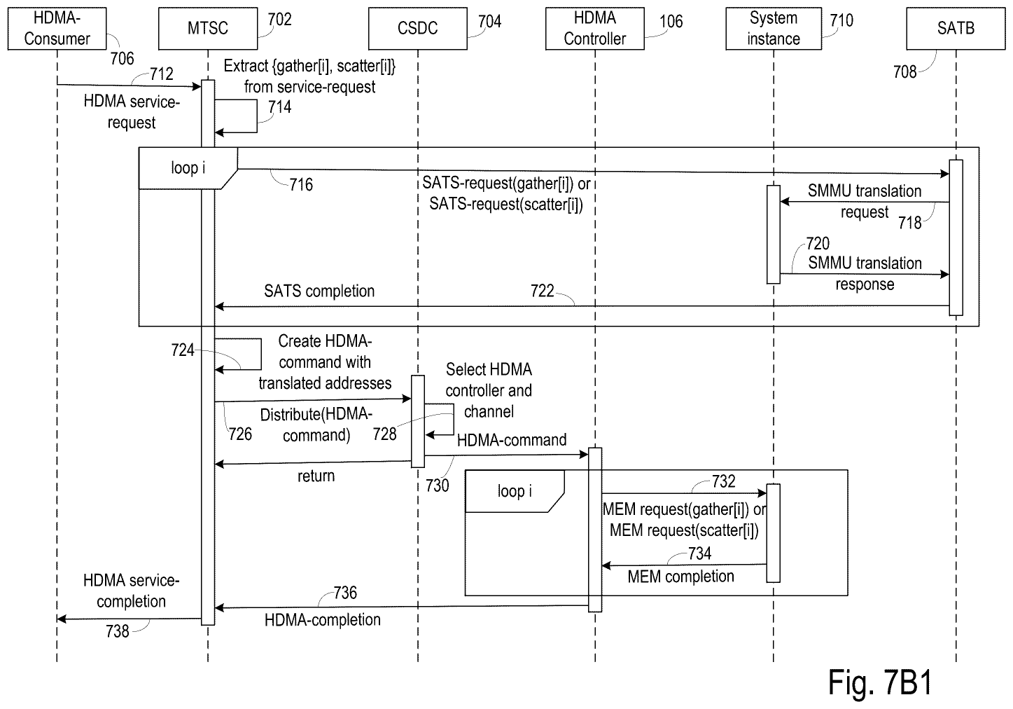

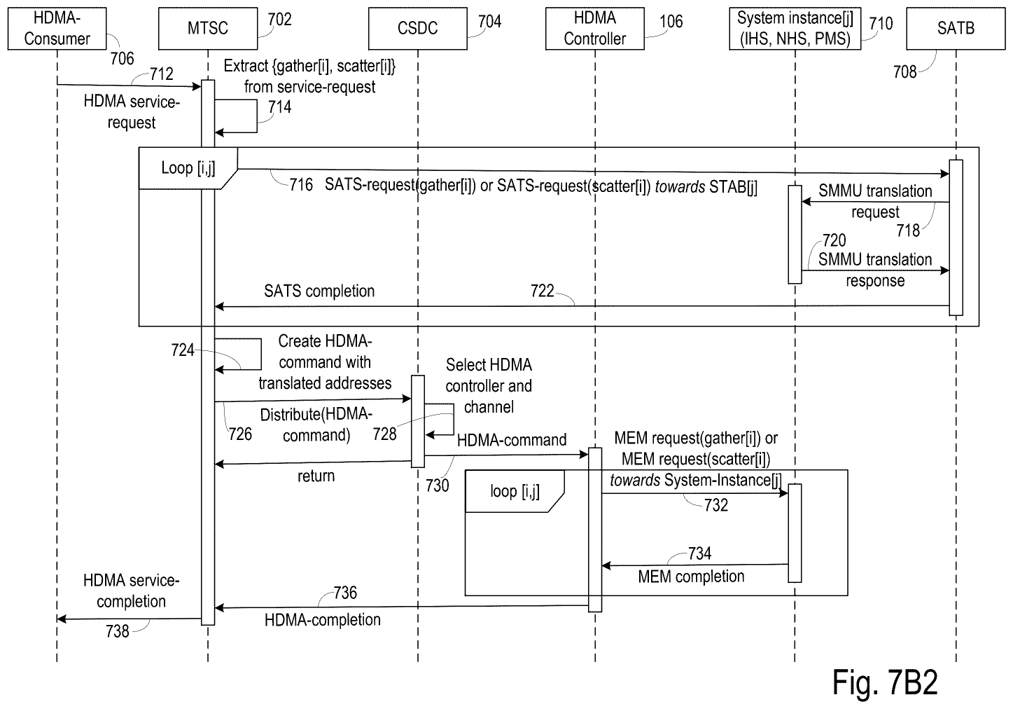

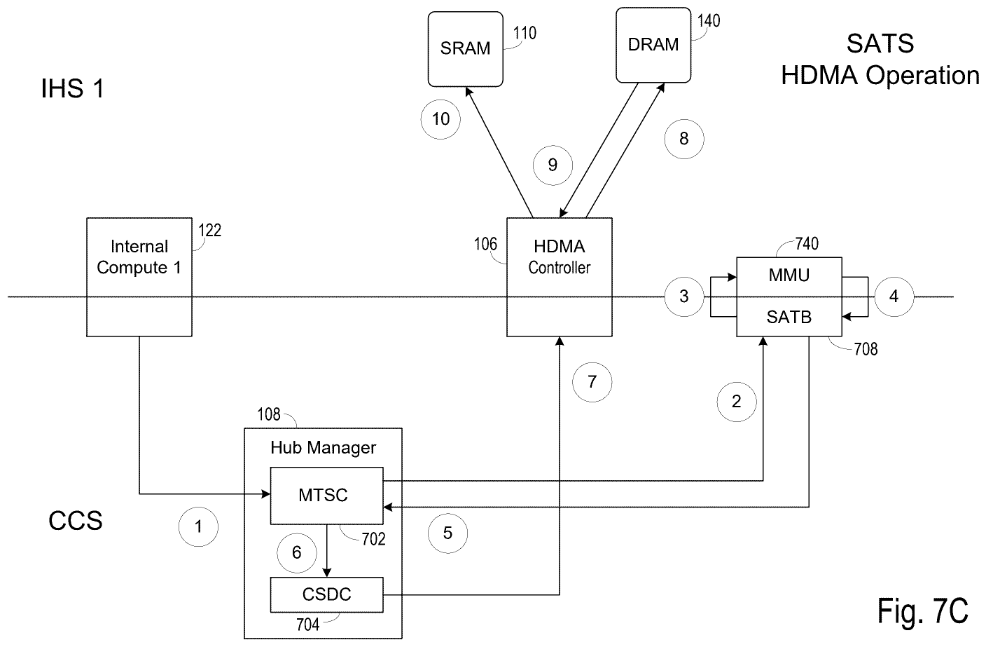

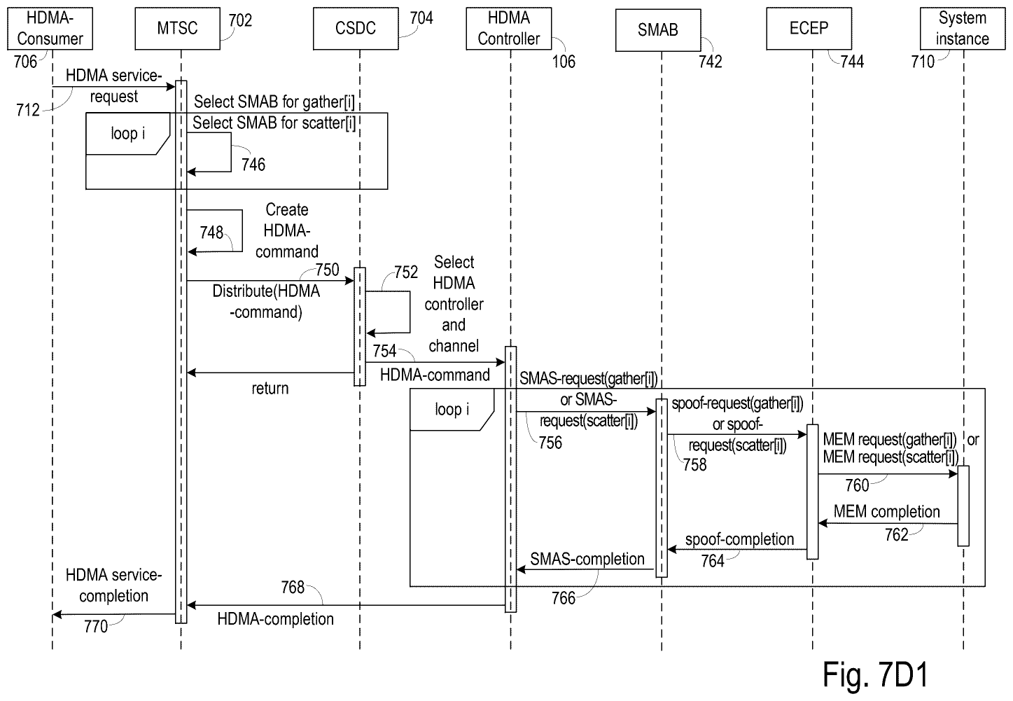

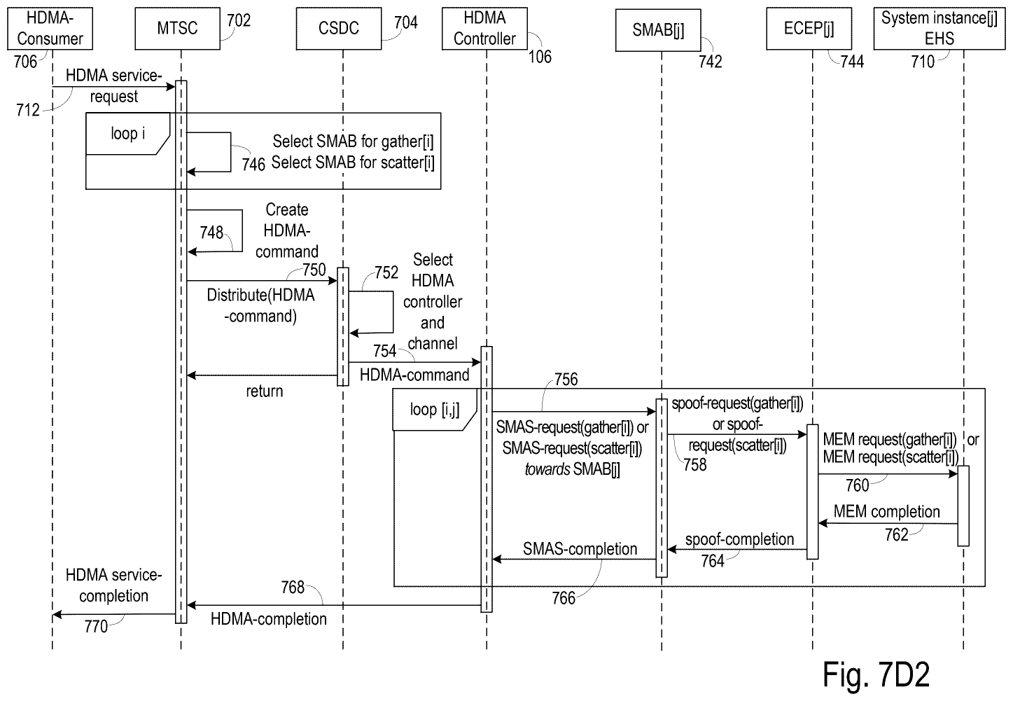

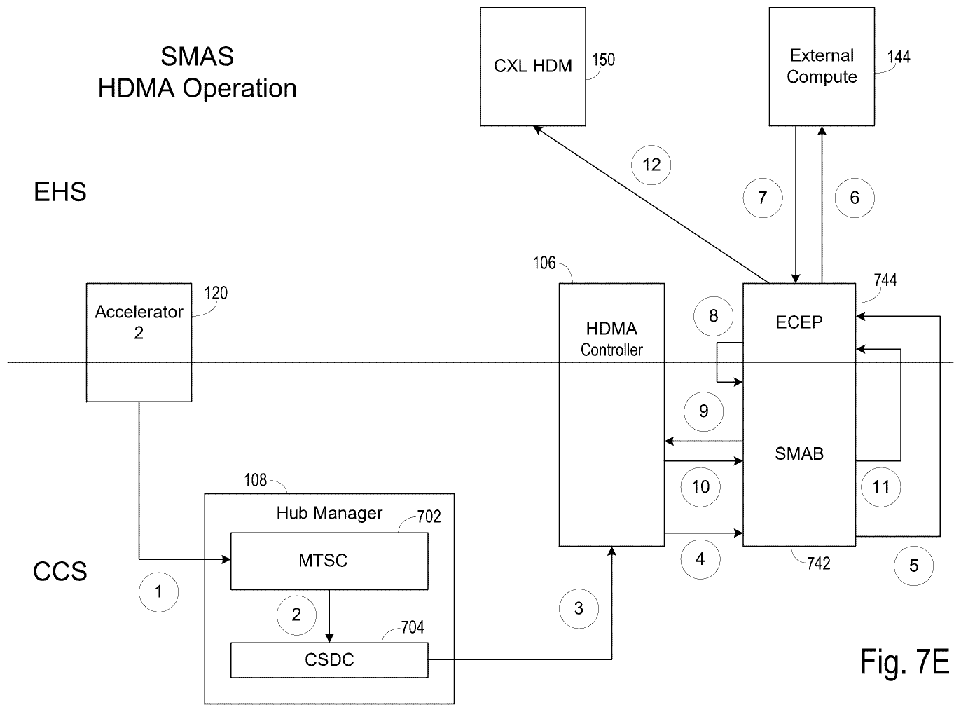

The chiplet hub 102 includes a hub DMA (HDMA) controller 106. FIG. 7A is an illustration of the connections between the HDMA controller 106, the various devices and the various memories. The devices, such as accelerator 1 118, accelerator 2 120, internal compute 1 122, internal compute 2 124, and embedded accelerator 104 are connected through the chassis fabric 6602 to the HDMA management module 528 of the hub manager 108. The HDMA management module 528 controls the operation of the HDMA controller 106 and provides a Memory Transaction Spoofing Controller (MTSC) 702 and a Chassis Service Distribution Controller (CSDC) module 704. The CSDC module 704 is a load balancer to balance the various HDMA requests among the various channels available in the HDMA controller 106. The MTSC 702 is an HDMA service request coordinator, i.e. it receives the HDMA service requests and coordinates their execution. The MTSC 702 and the CSDC 704 combine to manage the flow of DMA requests operating in the system 98. If the flow of HDMA requests is such that no channels are available for immediate use, the CSDC 704 queues HDMA commands for operation.

It is understood that for the internal compute 1 122 and internal compute 2 124 to obtain HDMA services, internal compute 1 122 and internal compute 2 124 need a hardware component configured to provide and receive messages in the chassis plane or instance CCS 160 or chassis fabric 6602. In one embodiment this hardware component is memory mapped within the internal compute chiplet to allow the CPU cores of the internal compute to generate HDMA service requests and receive completions.

As illustrated in FIG. 7A, the HDMA controller 106 is connected to each of the various system instances EHS 172, IHS 1 168, IHS 2 170, NHS 1 164, NHS 2 166, and PMS 162. This allows not only automated transfers among the various units inside a given system instance but also allows for the transfer of data between system instances. Because the HDMA controller 106 is a separate device and not included in any specific system instances, HDMA transactions require being able to obtain the proper addresses to be used in each system instance. In some cases, where data transfers between a device and memory are encrypted, the HDMA transactions need access to the relevant encryption keys. To this end, the HDMA transactions spoof the transactions of a selected requester agents. Elements in the chiplet hub 102 operating in the chassis plane and managed by the hub manager 108 communicate with elements present in the system instances where DMA transactions are desired to be performed to obtain the physical addresses and encryption keys in the relevant system instances. This is referred to as spoofing. The MTSC 702 is a spoofing controller to orchestrate the transaction spoofing for each HDMA service request. There are two types of HDMA operations, Spoofed Address Translation Service (SATS) and Spoofed Memory Access Service (SMAS). SATS can be used when the MMU for the target system instance is implemented within the chiplet hub 102 or any of its attached chiplets (e.g. MMU 2606 within accelerator 1 118). In SATS operation the HDMA controller need only spoof a requester agent when performing an address translation request towards an MMU for the target system instance in order to receive the proper physical addresses which it can then use to issue the memory transactions, therefore SATS operation can only be used in system instances of IHS, NHS, and PMS types. SMAS can be used when the MMU for the target system instance is not implemented within the chiplet hub 102 or any of its attached chiplets, therefore addresses may only be translated outside of the system instance, such as system instances of EHS type for which requester agents must include the ID of the initiator device on all memory transactions for the external MMU to perform the correct address translation. In SMAS operation the HDMA spoofs the complete memory transactions by relying on ECEP modules already present in the system instance (e.g. ECEP 4612 in FIG. 6E) to provide the HDMA memory transactions on behalf of the HDMA controller. While the SATS operation can spoof both physical and emulated requester agents, the SMAS operation can only spoof emulated requester agents. Both types of HDMA operations are detailed below.

SATS operation is illustrated in FIGS. 7B1, 7B2 and 7C. FIGS. 7B1 and 7B2 are ladder diagrams illustrating the HDMA transactions in SATS mode. The transactions are performed and managed by the HDMA management module 528, specifically the MTSC 702 and the CSDC module 704. An HDMA consumer 706, such as internal compute 1 122 or accelerator 3 126, provides an HDMA service request transaction 712 through the chassis fabric 6602 to the MTSC 702. The HDMA service request transaction provides a gather element list and a scatter element list, where each gather element in the gather element list indicates the source system instance to gather from, the source requester agent to be spoofed for reading, the source addresses to read from, and the amount of data to read, while each scatter element in the scatter element list indicates the destination system instance to scatter towards, the requester agent to be spoofed for writing, the write addresses, and the amount of data to write. Both gather elements and scatter elements may indicate more information like virtual address space identifiers (VASID) to qualify the addresses provided. The MTSC 702 receives the HDMA service request and develops the various gather and scatter elements 714 needed to handle the service request. Then for each gather or scatter element, the MTSC 702 provides 716 a SATS request gather transaction or SATS request scatter transaction to a spoofed system memory address translation broker (SATB) 708 through the chassis fabric 6602. The SATB is an agent provided by the hub manager 108. The SATB 708 cooperates with an MMU in the target system instance 710 (i.e. either the source system instance for gathering, or the destination system instance for scattering) to determine the system instance physical memory address for the address provided by the HDMA consumer 706. The SATB 708 provides 718 an MMU translation request to the system instance relative to the SATS request transaction. The system instance 710 MMU returns 720 the response to the SATB 708, which in turn returns 722 the SATS completion carrying the translated address value to the MTSC 702. This operation loops until all of the particular gather or scatter elements have been evaluated and system instance physical addresses obtained. The MTSC 702 then creates 724 the various HDMA commands necessary to transfer data using the translated addresses. The MTSC 702 provides 726 these HDMA command transactions to the CSDC 704. The CSDC 704 determines 728 an appropriate HDMA controller 106 and the appropriate HDMA channel in the selected HDMA controller, to perform the memory transactions associated with the HDMA command. The HDMA controller 106 can contain multiple channels and multiple HDMA controllers 106 can be present in the system 98 if desired. The CSDC 704 operates to load balance HDMA commands between the various channels. Once the HDMA controller and HDMA channel for each HDMA command have been determined, the HDMA command transactions are provided 730 to the selected HDMA controller, such as HDMA controller 106. For each particular HDMA command, the selected HDMA channel within the HDMA controller 106 performs 732 the appropriate memory transactions for gather (reading) or scatter (writing) and provides the associated memory transaction request to the system instance 710 to retrieve the data from the appropriate memory and then to provide the data to the appropriate memory for the desired memory transfer. After the HDMA memory transaction request is completed, a completion notification 734 is provided. After all of the memory transaction completions have been received, an HDMA command completion indication is provided 736 from the HDMA controller 106 to the MTSC 702, which in turn provides 738 an HDMA service completion to the HDMA consumer 706.

The operations of FIG. 7B1 have been illustrated for simplicity with all memory transfers inside the same system instance, such as between two different memories or two different memory locations in a single memory in the same system instance. The operation of the HDMA is not so limited and can transfer data between memory locations as defined by two separate system instances or more. FIG. 7B2 illustrates this operation. To perform the HDMA service across multiple system instances, the looping steps of 716, 718, 720, 722, 732, and 734 have been modified to operate both for each particular gather or scatter element and on each particular system instance. The variables i and j represent the gather or scatter element and the given system instance respectively, where it must be understood that each iteration of the variable i (i.e. the i-th scatter or gather element) will only be effectively associated with a single system instance (i.e. a single iteration of the variable j). In this manner the various requests are provided and translations received from the appropriate system instance, so that the MTSC 702 will have obtained the proper physical addresses for each of the gather or scatter elements from each of the relevant system instances. A different SATB 708 will be used in each system instance, along with an MMU in each system instance. In one embodiment, a different SATB is provided for each different MMU in each system instance, so that the SATB effectively becomes an extension of a platform native MMU. The HDMA controller 106 must similarly loop through not only the individual transfer transactions but the individual system instances as well to perform the various memory transactions of gathering and of reading and writing memory values. This is illustrated as looping through i and j variables for the memory requests.

SATS operation is illustrated block diagram form in FIG. 7C. The internal compute 1 122, the exemplary HDMA consumer 706, provides an HDMA service request to the MTSC 702 in operation 1. The MTSC 702 in operation 2 provides the request to the SATB 708 to cooperate with an MMU 740 that is present in the appropriate system instance. The SATB 708 provides the untranslated addresses in operation 3 and the MMU 740 returns the translated addresses in operation 4. The translated addresses are returned by the SATB 708 to the MTSC 702 in operation 5. In operation 6, the MTSC 702 provides the HDMA commands with these translated addresses to the CSDC 704 for load balancing and then the CSDC 704 provides the various HDMA commands in operation 7 to the HDMA controller 106. The HDMA controller 106 in operation 8 provides a memory read transaction to the DRAM 140, as the exemplary memory data source, as operation 8 and receives the read data in operation 9. The HDMA controller 106 then writes the received data to the SRAM 110, the exemplary destination data location, in operation 10. Of interest to note in FIG. 7C is that to perform the full HDMA operations, various operations happen both in the chassis plane of CCS 160 and in the memory plane of the system instance of the particular request, in this case IHS 1 168. The HMDA consumer, normally operating in the memory plane, also operates in the chassis plane to provide the HDMA request. The HDMA controller 106 operates in the memory plane and the chassis plane to do HDMA operations. The hub manager 108 operates only in the chassis plane. The SATB 708 is in the chassis plane but it can communicate with an MMU in the system instance memory plane to obtain the translation of the addresses.

In referring now to FIG. 7D1, SMAS operation is illustrated. As before, in operation the HDMA consumer 706 provides in HDMA service request transaction 712 to the MTSC 702. The MTSC 702 determines this must be an SMAS operation because one of the memory locations requires external address translation. The MTSC 702 loops and determines 746 particular spoofed system memory access brokers (SAMBs) be to be used to perform spoofing of each gather element and each scatter element. After the various SMAB units have been determined, the MTSC 702 creates 748 the necessary HDMA commands. The HDMA command transactions are provided 750 to the CSDC 704. The CSDC 704 determines 752 the appropriate HDMA controller and HDMA channel for each HDMA command. The HDMA command transactions are provided 754 to the selected HDMA controller, such as HDMA controller 106. The selected HDMA channel within the selected HDMA controller 106 then provides 756 a SMAS request transaction for each scatter or gather element to the appropriate SMAB 742 through the chassis fabric 6602. The SMAB is an agent provided by the hub manager 108. The SMAB 742 is used to provide a spoofing transaction when the system instance physical memory address is not available directly to the HDMA controller 106 but rather is translation must be performed outside the SiP 100 containing the chiplet hub 102 by an external unit, such as the external compute 144. The SMAB 742 receives the particular SMAS request transaction and develops a spoof request, which is then provided 758 to an ECEP 744. The ECEP 744 is emulating an endpoint and thus can access the system used by the external compute 144 to have the memory transactions translated in normal operation of the external compute 144. The ECEP 744 provides 760 the various memory transactions request to gather (reading) or scatter (writing) the requested data. The system instance 710 performs the various memory transactions. Each of these memory transactions results in a completion provided 762 to the ECEP 744. A spoofing completion is provided 764 from the ECEP 744 to the SMAB 742 for each completed spoof request. The SMAB 742 in turn provides 766 an SMAS completion to the HDMA provider 106 for each completed SMAS request. Once all the gather and scatter memory transactions for an HDMA command have been completed, the HDMA controller 106 provides 768 an HDMA command completion indication to the MTSC 702. The MTSC 702 provides 770 an HDMA service completion to the HDMA consumer 706.

As with the description of FIG. 7B1, the description of FIG. 7D1 also focuses on a single system instance, but just as with FIG. 7B2 in the case of SATS operations, SMAS operations can also operate in multiple system instances as illustrated in FIG. 7D2. Operation with multiple system instances, is varied from single system instance operation by looping the various SMAS request and spoof requests and then resulting memory requests for each of the particular system instances, as indicated by the i, j indices in the loop.

SMAS operation is illustrated in FIG. 7E. The operation illustrated in FIG. 7E is the transfer of data from the memory made available by the external compute 144 into CXL HDM 150. In operation 1 the accelerator 2 120, as the HDMA consumer, provides the HDMA service request to the MTSC 702. The MTSC 702 provides the HDMA commands in operation 2 to the CSDC 704 to be load balanced and then provided to the HDMA controller 106 in operation 3. In operation 4, which is noted to be a CCS system instance or chassis plane operation, the SMAS requests that form the gather portion of the gather/scatter operations needed to read from external compute 144 and write to CXL HDM 150, the SMAS-request gather 756, are provided to the SMAB 742 to interoperate with the ECEP 744 in operation 5 as spoof-request gather 758. In operation 6, the ECEP 744 provides a read or gather request, the MEM request gather 760, to the external compute 144 and that read data is returned in operation 7 as the MEM completion 762. In operation 8, the ECEP 744 provides the returned data to the SMAB 742 as the spoof-completion 764. In operation 9, the SMAB 742 provides the read or gather data to the HDMA controller 106 as the SMAS-completion 766. With the read or gather operation complete, the scatter or write operation is performed. In operation 10, the HDMA controller 106 provides the read data, now the write data, to the SMAB 742 as the SMAS-request scatter 756. In operation 11, the SMAB 742 provides the write or scatter data to the ECEP 744 as the spoof-request scatter 758. Finally, the ECEP 744 writes the data to the CXL HDM 150 as MEM request scatter 760 in operation 12.

While SATS and SMAS operations have been described separately, it is understood that SATS and SMAS operations may be combined in a single HDMA request operation, depending on the memory locations specified in the scatter or gather element list.

In some embodiments, the MTSC 702 prioritizes HDMA operations according to provided priority rules or physical location within the chiplet hub 102.

With this configuration, where the HDMA operations are performed primarily through a control plane under the control of a separate agent, with only the actual memory reads and writes performing in the memory or system instance plane, the HDMA service requests can be provided from any HDMA consumer in the system, not just the designated host system. For example, in a non-hosted system, any of the desired accelerators can provide HDMA service requests to the MTSC 702 in the chassis plane. In an internally or externally hosted system, compute devices other than the host and any accelerators can provide the HDMA requests. This is an improvement on normal DMA operation, where the host must provide the operations to the DMA controller. By the use of the hub manager and the MTSC, no host involvement is required in any DMA operations and DMA operations can occur in a non-hosted environment.

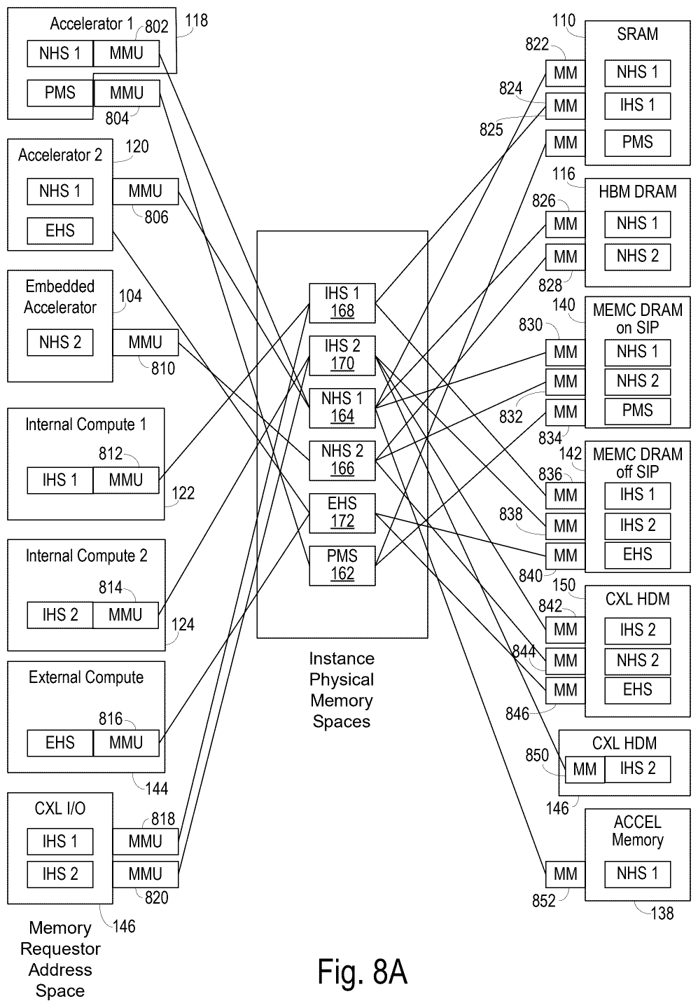

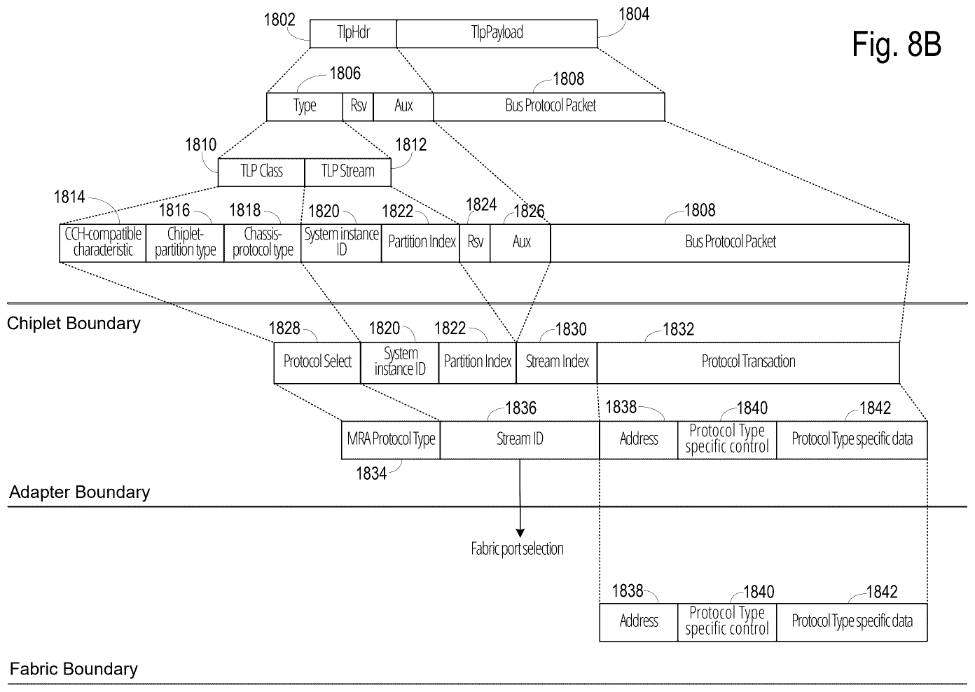

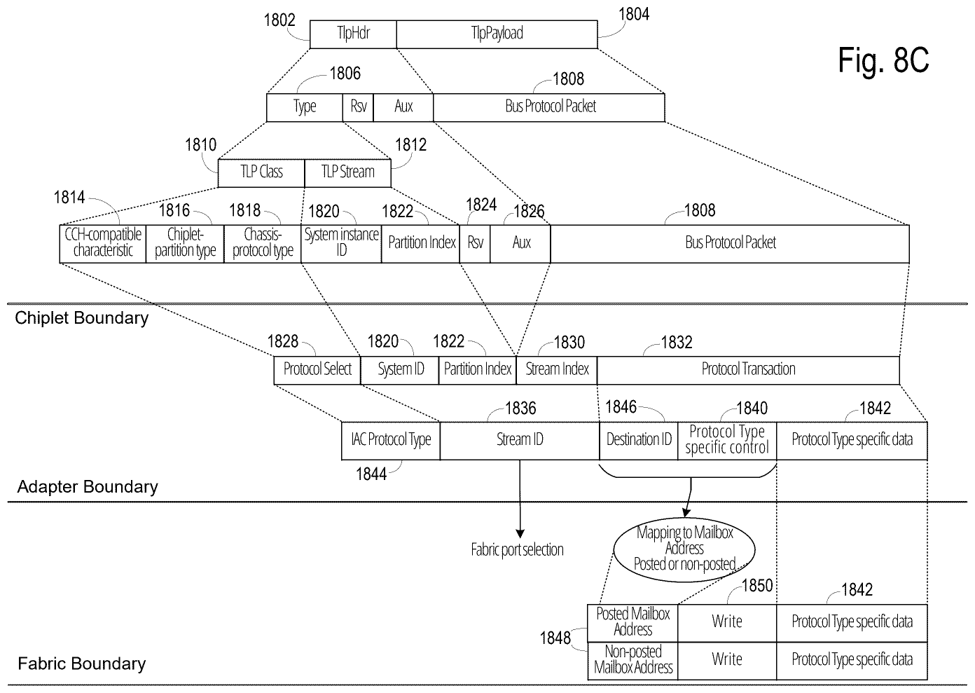

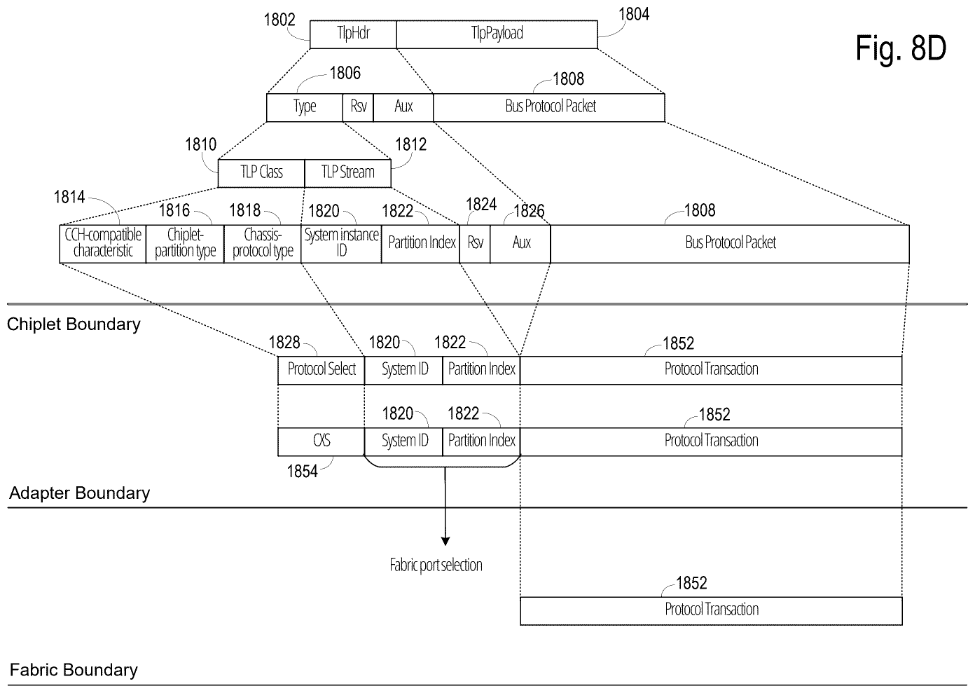

FIG. 8A illustrates memory mapping in the system 98. In overview, each of the devices has its own address space, which is then translated to a physical memory space for the appropriate system instance, which address is then mapped to the appropriate physical memory of the memory device.

Accelerator 1 118 is part of system instances NHS 1 164 and PMS 162. An MMU 802 is provided inside the accelerator 1 118 to translate addresses from accelerator 1 118 for use by the NHS 1 164 system instance. An MMU 804 is also provided to translate addresses from the accelerator 1 118 for the PMS system instance 162, as the two environments present on accelerator 1 118 to operate in both the NHS 1 164 and PMS 162 system instances use memory addresses differently.

Accelerator 2 120 is attached to the NHS 1 164 system instance and the EHS 172 system instance. An MMU 806 is provided to translate accelerator 2 120 addresses for the NHS 1 164 system instance. An MMU is not needed for the EHS system instance 172, as chiplet hub-provided MMUs are not necessary in externally hosted system instances The embedded accelerator 104 is in the NHS 2 166 system instance and MMU 810 is provided to translate between the embedded accelerator 104 and the physical address space of NHS 2 166. Internal compute 1 122 is in the IHS 1 168 system instance and an MMU 812 is inside internal compute 1 122 to translate the addresses from the address space of the internal compute 1 122 to the physical memory space of the IHS 1 168 system instance. Internal compute 2 124 is in the IHS 2 170 system instance and an MMU 814 is inside internal compute 2 124 provided to translate addresses. External compute 144 is in the EHS system instance 172 and includes an MMU 816 to translate between the address space of the external compute 144 and the physical memory space of the EHS 172 system instance. CXL I/O 148 is in the IHS 1 168 system instance and the IHS 2 170 system instance. An MMU 818 is provided to translate memory addresses of the CXL I/O 148 for the IHS 1 168 system instance and an MMU 820 is provided to translate addresses for the CXL I/O 148 for use with the IHS 2 170 system instance.

Looking now at the memories, SRAM 110 is in the NHS 1 164 system instance and a memory mapper 822 is provided to map from the NHS 1 164 physical memory space to the physical memory space of the SRAM 11. SRAM 110 is also a part of the IHS 1 168 system instance and a memory mapper 824 is provided to map from the IHS 1 168 physical memory space to the physical memory space of the SRAM 11. SRAM 110 is also a part of the PMS 162 system instance and a memory mapper 825 is provided to map from the PMS 162 physical memory space to the physical memory space of the SRAM 11. The HBM DRAM 116 is in the NHS 1 164 system instance and the NHS 2 166 system instance. A memory mapper 826 is provided for translating from the NHS 1 164 physical memory space to the physical memory space of the HBM DRAM 116. A memory mapper 828 is provided to translate from the NHS 2 166 physical address space to the physical address space of the HBM DRAM 116.

DRAM 140 is a part of three different system instances, NHS 1 164, NHS 2 166 and PMS 162. A memory mapper 830 is provided for use with the NHS 1 164 system instance, while a memory mapper 832 is used with the NHS 2 166 system instance and a memory mapper 834 is used with the PMS 162 system instance. DRAM 142 is involved with three different system instances, in this case IHS 1 168, IHS 2 170 and EHS 172. A memory mapper 836 is used to translate between the IHS 1 168 physical memory address space and the physical address space of the DRAM 142. A memory mapper 838 is used to translate between the IHS 2 170 physical address space and the physical address space of the DRAM 142. A third memory mapper 840 is used to convert from the physical memory addresses of the EHS 172 system instance to the memory space of the DRAM 142.

The CXL HDM 150 is included in three system instances, one IHS 2 170, NHS 2 166 and EHS 172. A memory mapper 842 is provided to translate from the IHS 2 170 physical memory space to the physical memory space of the CXL HDM 150. A memory mapper 844 is provided to translate between the NHS 2 166 memory space and the CXL HDM 150 memory space. A memory mapper 846 is provided to memory map between the EHS 172 system instance address range and the physical addresses of the CXL HDM 150. CXL HDM 146 is in the IHS 2 170 system instance includes a memory mapper 850 to translate addresses as appropriate per CXL standards. The memory 138 contained in the accelerator 1 118 is a portion of the NHS 1 164 partition. A memory mapper 852 is used to translate between the NHS 1 162 system instance and the physical memory of the accelerator memory 138.

Packets undergo a series of transitions from the D2D link through the link services through adapter pipelines to the fabric 400. FIGS. 8B, 8C and 8D illustrate the changes in the three different types of packets. FIG. 8B illustrates memory type transactions (i.e. address-routed), while FIG. 8C illustrates message and similar ID-routed transactions and FIG. 8D illustrates transactions where the entire bus protocol packet is simply tunneled through from the D2D link to the receiving device.

Referring now to FIG. 8B, is noted that the notation of the BoW or bunch of wires standard is utilized. The BoW standard is produced by the Open Chiplet System workstream under the Open Chiplet Economy sub-project under the Server Project of the Open Compute Project. As of the filing of this application, the BoW 2.0 Specification, a PHY specification, and the Link Layer Specification Rev A were published.

At the highest level, the packet includes a transaction layer packet (TLP) header 1802 and a TLP payload 1804. The TLP header includes a type value 1806. The TLP payload 1804 is a bus protocol packet 1808 corresponding to the protocol of the packet. The type value field 1806 breaks down into a TLP class 1810 and a TLP stream 1812. In turn, the TLP class field 1810 breaks down into a CCH compatible characteristic 1814, a chiplet partition type 1816 and a chassis protocol type 1818. Chassis protocol type can represent transaction spaces such as MEM, SNP, MSG, PMSG, CFG, INT, etc. The TLP stream 1812 breaks down into a system instance ID 1820 and a partition index 1822. The system ID 1820 and partition index 1822 together identify the particular partition within a specific system instance, as described above, where the packet is directed. Therefore, the packet that is transmitted across the D2D link of the chiplet boundary includes the CCH compatible characteristic 1814, the chiplet partition type 1816, the chassis protocol type 1818, the system instance ID 1820, the partition index 1822, a reserved field 1824, an aux field 1826 and the bus protocol packet 1808.

This packet is received by the link services portion of the D2D link on the receiving chiplet. The CCH compatible characteristic 1814, the chiplet partition type 1816 and the chassis protocol type 1818 form a protocol select field 1828 used to select the proper path through the link services block as described below. The system instance ID 1820 and partition index 1822 are carried forward. The bus protocol packet 1808 is separated into a stream index 1830 and a protocol transaction 1832. As the illustration of FIG. 8B is for an MRA protocol type, the value of the protocol select field 1828 is an MRA protocol 1834. Examples of MRA protocols are memory (MEM), PCI memory (PMEM), I/O (IO) and memory-mapped interrupts (INT-MM). The system instance ID 1820, the partition index 1822 and the stream index 1830 are combined to create a stream ID 1836, which forms the value used to select a particular port on the fabric 400. The protocol transaction 1832 breaks down into an address field 1838, a protocol type specific control 1840 and protocol type specific data 1842. This breakdown from the protocol transaction 1832 is available knowing that this is an MRA protocol type 1834. With the stream ID 1836 developed to select the port, the address 1838, the protocol type specific control 1840 and the protocol type specific data are provided to the fabric 400 for switching to the destination indicated by the address. This is because for MRA or memory transactions the fabric 400 routes based on the address value 1838.

FIG. 8C indicates the packet evolution for an IAC packet type which includes items such as messages (MSG), PCI message (PMSG), config (CFG), native interrupts (INT) and completions. IAC protocols are routed based on a destination ID rather than a memory address. The protocol select field 1828 is the IAC protocol type 1844 and the stream ID 1836 is developed in the manner as in the MRA type. Stream ID 1836 is again used for fabric port selection. The protocol transaction field 1832 breaks down into a destination ID 1846, a protocol type specific control 1840 and protocol type specific data 1842. The combination of the destination ID 1846 and the protocol type specific control are used to map to a mailbox address used to receive the messages, configurations or interrupts. Values received in the particular mailbox of the particular device, the protocol type specific data 1842, are then operated on according to the actual message, configuration or interrupt value. After mapping to the mailbox address, the mailbox address field 1848 is provided with a write protocol type specific control value 1850, as all mailbox transactions are writes, and the protocol type specific data 1842. Therefore, the mailbox address is provided to the fabric 400 to be used by routing but only after the destination and protocol type specific control have been decoded into a mailbox address. Therefore, IAC type transaction as still considered as being destination routed.

FIG. 8D illustrates a tunneling transaction packet, which is routed by IPB identity. In some system instances a packet is simply tunneled from one chiplet to another chiplet, without operating on or interpreting the contents of the particular packet. That transaction is illustrated in FIG. 8D. The protocol select 1828, system instance ID 1820 and partition index 1822 values are obtained as described above. The bus protocol packet 1808 becomes the protocol transaction 1852 without being processed by a protocol adapter. The protocol select field 1828 value is a CXS value 1854 indicating the tunneling transaction. The system instance ID value 1820 and the partition index 1822 are used for fabric port selection and the protocol transaction 1852 is provided with no further changes. The only value provided to the fabric 400 is the protocol transaction 1852, which is routed by the fabric based on the point-to-point determination based on fabric port selection.

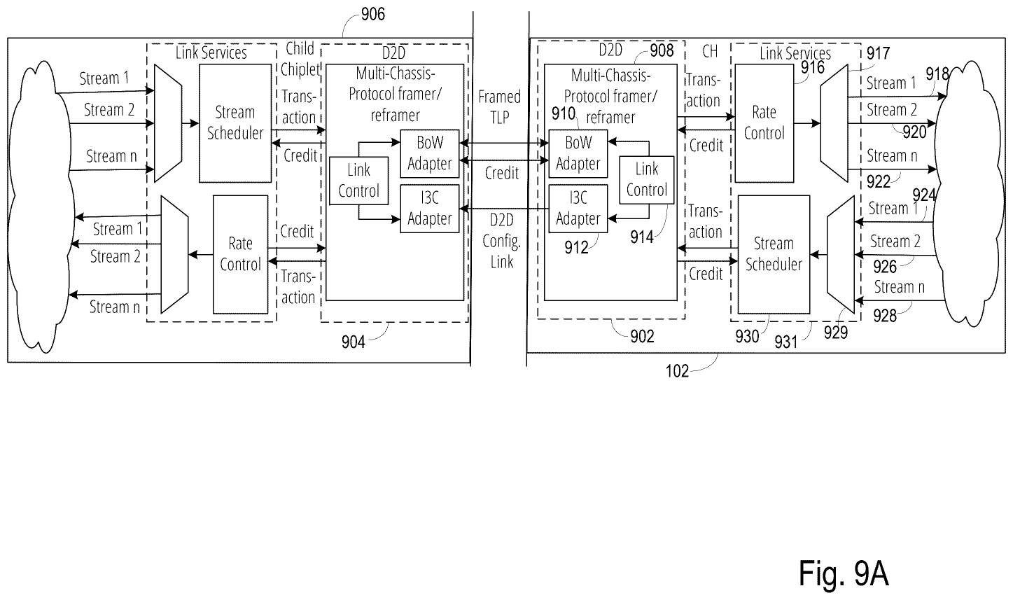

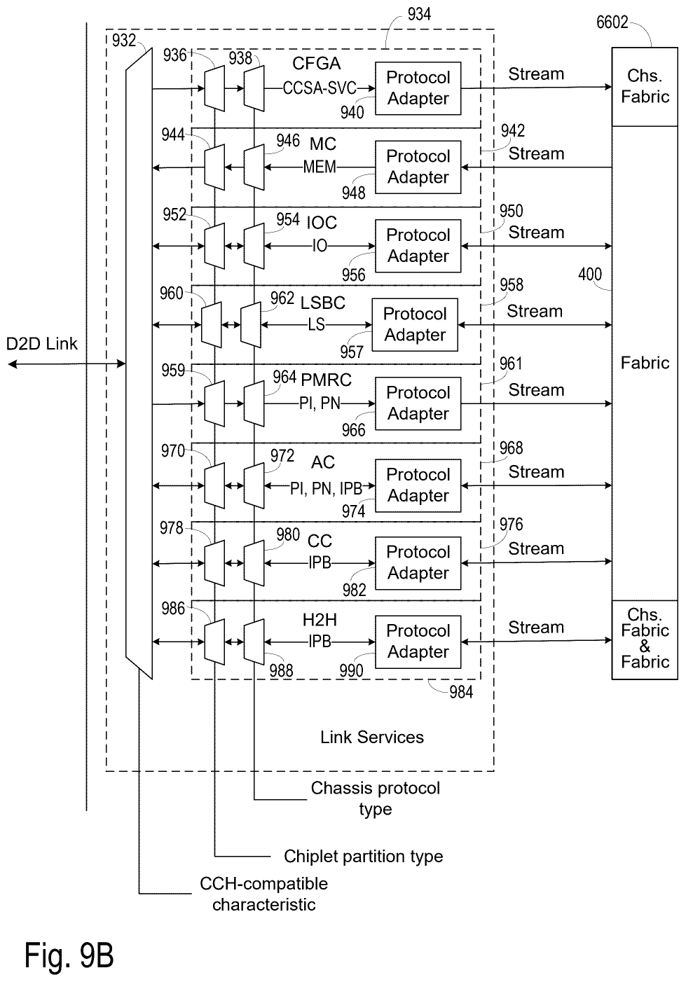

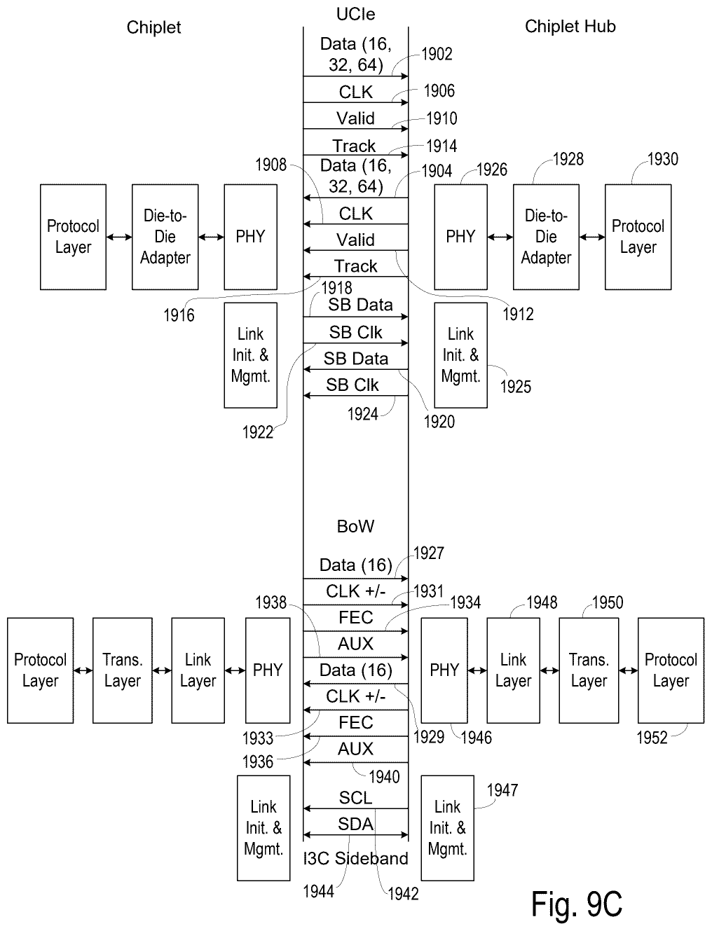

As mentioned above, the BoW standard is utilized in many of the examples in this specification. FIG. 9A provides the exemplary details on the D2D link edge portion of each chiplet. The PHY of a BoW link is not illustrated. A D2D 902 is present on the chiplet hub 102 and an equivalent D2D 904 is present on a child chiplet 906. The components in the D2D portion 904 and the D2D portion 902 are identical and only the D2D portion 902 will be described. A multi chassis protocol framer/deframer 908 is provided. The multi chassis protocol framer/deframer 908 includes a BoW adapter 910 and an I3C adapter 912. The BoW adapter 910 handles the exchange of the transaction layer packet (TLP) and the return of any flow control credit, while the I3C adapter 912 is a sideband signal which is used for configuration of the D2D link. Link control 914 is connected to the BoW adapter 910 and the I3C adapter 912 to perform link level transactions of each protocol.

Received transaction layer packets from the child chiplet 906 to the chiplet hub 102 are provided by the multi chassis protocol framer/deframer 908, specifically the BoW adapter 910, to a rate control module 916. The rate control module 916 performs rate control operations on the particular outgoing streams. A demultiplexer 917 splits the transaction flow into separate outgoing streams, such as stream 1 918, stream 2 920 and stream n 922. Rate control credit is returned from the rate control module 916 to the multi chassis protocol framer/deframer 908 which further provides them to the child chiplet 906 as framed TLPs.

Incoming streams such as stream 1 924, stream 2 926 and stream n 928 are multiplexed by multiplexer 929 and provided to a stream scheduler 930. The transactions of the particular streams are arranged by the stream scheduler 930 and provided to the BoW adapter 910. Rate control credit returned by the rate controller within the child chiplet 906 is received as framed TLPs by the multi chassis protocol framer/deframer 908, which in turn provides it to the stream scheduler 930 to allow it to continue to provide packets to the BoW adapter 910. The rate control 916, stream scheduler 930, demultiplexer 917 and multiplexer 929 are a portion of link services 931

Operation of the multiplexer 929 and the demultiplexer 917 is illustrated in FIG. 9B. The illustrated blocks are in the chiplet hub 102. Similar blocks are present in a child chiplet hub and relevant blocks are present in a child chiplet. The illustrated block demultiplexes transactions received over the D2D link into protocol-based streams and multiplexes protocol-based streams into a transaction flow over the D2D link. Packets as illustrated in FIGS. 8B, 8C and 8D above the chiplet boundary are present on the D2D link. Inbound packets from the D2D link enter a multiplexer/demultiplexer 932, which is controlled by CCH-compatible characteristic field 1814, which defines the functional interfaces implemented by the child chiplet 906 on the opposite end of the D2D link. Example CCH-compatible characteristics include chassis configuration (CFGA) which is mandatory for all chiplets to support, memory characteristic (MC), I/O characteristic (IOC), load/store bridge characteristic (LSBC), private memory requester characteristic (PMRC), accelerator characteristic (AC), compute characteristic (CC), and chiplet hub to chiplet hub (H2H). The H2H CCH-compatible characteristic is mutually exclusive with all other characteristics except for the mandatory CFGA, which means a child chiplet 906 may either present the CFGA and H2H characteristics only or it may present the CFGA plus any combination of all other characteristics. The demultiplexer 932 performs a first splitting of the received packets into these flows. These flows are then processed in a characteristic block. Illustrated blocks are CFGA 934, MC 942, IOC 950, LSBC 958, PMRC 961, AC 968, CC 976 and H2H 984. CFGA characteristic is mandatory for any child chiplet 906 that is not another chiplet hub and is not allowed for any child chiplet 906 that is a chiplet hub. MC represents a functional profile for memory providers that may only complete MRA type transactions. IOC represents a functional profile for PPB-equivalent providers which enable enumeration, discovery, configuration and transaction bridging following PCI/CXL semantics. LSBC represents a functional profile for MRA type transaction bridging from/to external memory fabrics with load/store semantics (e.g. CXL.mem fabric). PMRC represents a functional profile for MRA type transaction initiators of private memory provided by chiplet hub 102. AC represents a functional profile for application-specific accelerators which may initiate and complete transactions of MRA, IAC and CXS (IPB) types. CC represents a functional profile for CPU implementing Internal Hosts, which may initiate and complete transactions of CXS (IPB) type only. H2H is mandatory for chiplet hubs as it represents an inherent characteristic for a chiplet hub to be clustered with more chiplet hubs and is not allowed on any child chiplet 906 that is not a chiplet hub. A child chiplet 906 that is not a chiplet hub may implement any combination of MC 942, IOC 950, LSBC 958, PMRC 961, AC 968 and CC 976. Each CCH-characteristic supports distinct modes of operation. For example, the MC characteristic includes platform-independent memory control and platform-native memory control. The IOC characteristic includes root port, upstream switch port and downstream switch port. The LSBC characteristic includes inbound bridge, outbound bridge or bidirectional bridge. The PMRC characteristic includes platform independent addressing and platform native addressing. The AC and CC characteristics similarly relate to the configurations of the accelerators and computes, where AC supports both expander modes and non-expander modes, while CC supports only expander modes. Demultiplexers 936, 944, 952, 960, 959, 970, 978 and 986 present in each characteristic block separate each characteristic into finer grained flows according to the operation mode for the associated characteristic through use of the chiplet-partition type field 1816.

A third tier of demultiplexers 938, 946, 954, 962, 964, 972, 980 and 988 then even more finely separate the flows or streams by using the chassis-protocol type field 1818 to further separate the various characteristic streams. Protocol types include MRA, IAC and CXS (IPB).

In one embodiment, each tier of demultiplexers removes its relevant field from the header of the packet. In another embodiment, the third tier of demultiplexers removes all three of the CCH-compatible characteristic field 1814, the chiplet-partition type field 1816 and the chassis-protocol type field 1818. The third tier demultiplexer adds the protocol select field 1828 to the packet after the CCH-compatible characteristic field 1814, the chiplet-partition type field 1816 and the chassis-protocol type field 1818 are removed, as the third tier of multiplexers determines the finest grain of protocol for each stream.

In one embodiment, the third tier of demultiplexers removes the CCH-compatible field 1814, chiplet partition type filed 1816 and the chassis protocol type field 1820 and provides the protocol select field 1828. The protocol adapter removes protocol select field 1828 and the system ID field 1820, the partition index 1822 and the stream index 1830. In the outbound direction, the protocol adapter and third tier of multiplexers adds the respective fields to the packet.

Each characteristic block contains a series of protocol adapters, each shown as a single block in FIG. 9B. Illustrated protocol adapters are CFGA 940, MC 948, IOC 956, LSBC 957, PMRC 961, AC 974, CC 982 and H2H 990. The protocol adapters include some combination of adapter agents from the variety available in the adapter agent pool 6662 and internal service providers from the variety available in the internal service provider pool 6676 of the hub manager 108 as needed to convert between the attached chiplet and the fabric 400. For example, CXL I/O 148 in the IHS 1 168 system instance uses host bridge 622, MMU 624 and ITU 634 in the pipeline within its IOC protocol adapter 956, i.e. between the multiplexer 929 and demultiplexer 917 and the fabric 400. DRAM 142 has an EMAS 646, MM 647 and CHA 650 in the IHS 1 164 system instance but EMAS 646, MM 1607 and CHA 1608 in the IHS 2 170 system instance. Accelerator 2 120 for the NHS 1 164 system instance includes an ENNA 2628, MMU 2630, MM 2631 and PTSB 2632 in the protocol adapter pipeline. Other examples are provided in FIGS. 6A1 to 6F.

CXL HDM 150 is a slightly different configuration, as it does not have a D2D port but rather a CXL/PCI port. However, a similarly developed pipeline to present between the CXL HDM 150 and fabric 400. The pipeline is more complicated, only in part because of the fabric 1668 but also because of the desired functionality of being able to share a CXL HDM among devices that are not CXL HDM aware. Reference to FIG. 6B, 6D or 6E shows the various agents and services that are utilized.

In the embodiment described above with three layers of demultiplexers, the protocol adapters are for specific protocols and functions. In an alternate embodiment, the third tier of demultiplexers can be removed and the protocol adapters will handle all protocols for that characteristic.

The above description was a flow from the D2D link to the fabric 400. The flow from the fabric 400 to the D2D link is complementary, with multiplexers combining streams instead of demultiplexers splitting streams.

Reviewing FIGS. 6A1 to 6F, it is noted that in some cases, such as internal compute 122 in IHS 1 168, the I/O load and store chiplet 130 between CXL I/O 148 and the chiplet hub, internal compute 2 124 in IHS 2 170, accelerator 1 118 and accelerator 2 120 in NHS 1 164, and the I/O and load and store chiplet 136, various of these services are present in the chiplet of those devices. Components on those chiplets are required to provide those services, but those services are configured by the hub manager 108.

Details of two well-known D2D protocols are provided in FIG. 9C as examples. The first protocol is the UCIe protocol developed by the Universal Chiplet Interconnect Express Consortium. As of the preparation of the specification the UCIe specification was at revision 2.0, version 1.0 (dated Aug. 6, 2024). The second protocol is the bunch of wires or BoW protocol as previously described. In FIG. 9C, the UCIe protocol is illustrated at the top. The UCIe specification provides for 16,32 or 64 unidirectional data lines 1902 and 1904, unidirectional clock lines 1906 and 1908, unidirectional valid signals 1910 and 1912, and unidirectional tracking signals 1914 and 1916. The UCIe specification also provides for unidirectional sideband data channels 1918 and 1920 and unidirectional sideband clock channels 1922 and 1924. On each side of the D2D link, a PHY 1926 receives the electrical signals and appropriately converts them to be utilized by a die to die adapter 1928, which handles various link layer and other levels of the protocol. The die to die adapter 1928 is a connected to a protocol layer. A link initialization and management block 1925 is connected to the sideband signals SB Data and SB Clk.

The bunch of wires standard provides for 16 bits of unidirectional data 1927 and 1929, unidirectional differential clock signals 1931 and 1933, unidirectional forward error correction signals 1934 and 1936 and unidirectional auxiliary signals 1938 and 1940. Preferably I3C sideband signaling is provided with a clock line 1942 and a bidirectional data line 1944. The BoW standard defines a PHY layer 1946 connected to a link layer 1948 which is connected to a transaction layer 1950 which is then connected to the protocol layer 1952. A link initialization and management block 1947 is connected to the I3C sideband signals. These two standards, UCIe and BoW, are provided here in detail as references. It is understood that numerous other protocols could be utilized if desired or as they are developed in the future.

FIG. 10A illustrates a clustered chiplet hub (CCH) configuration 1000. Previous discussions have generally been directed to the operations of a single chiplet hub, such as chiplet hub 102, but chiplet hubs can be interconnected to form a clustered chiplet hub to provide greater capabilities for the SiP 100. Illustrated are four chiplet hubs CH-0 1002, CH-1 1004, CH-2 1006 and CH-3 1008. A D2D link, such as the illustrated Bunch of Wires and I3C links are connected between each of the chiplet hubs 1002, 1004, 1006 and 1008. Using these links, the chiplet hubs 1002, 1004, 1006 and 1008 can form integrated chassis and memory fabrics and provide integrated management services. As illustrated, each chiplet hub 1002, 1004, 1006 and 1008 has connected to it four child chiplets. Child chiplets CAC-0 1010, CAC-1 1012, CAC-14 1038 and CAC-15 1040 are connected to CH-0 1002. Similarly, child chiplets 1014, 1016, 1018 and 1020 are connected to CH-1 1004. In like fashion child chiplets 1022, 1024, 1026 and 1028 are connected CH-2 1006. Finally, child chiplets 1030, 1032, 1034 and 1036 are connected to CH-3 1008. Each of the child chiplets is connected to a chiplet hub using a D2D link which is similar to the interconnection between the chiplet hubs.

FIG. 10B is a flowchart of initialization and startup of a clustered chiplet hub configuration such as that of clustered configuration hub 1000. In step 1050, the power on reset signal is received by the clustered chiplet hub 1000. In step 1052, the root chiplet hub, such as CH-0 1002, loads the boot loader and boots the master CPU contained in the root chiplet hub. In step 1056, the root chiplet hub master CPU initializes the static CCS three two D2D links to initialize the connected to child chiplet hubs and four D2D links to the child chiplets. From the view of the root chiplet hub, all of the connected chiplets that connected, even the chiplet hubs, are considered child chiplets at this stage. As there are D2D links to initialize, in step 1060 the D2D controller boot image is provided to a link initialization and management block in the remote D2D controller for that link over the I3C link sideband provided in the D2D link. The link initialization and management block contains a very small controller utilized to just initialize the D2D link based on information received from the I3C link. In step 1062, the D2D controller operates using the boot image to initialize the D2D link between the chiplet hub and the child chiplet using the I3C link for communication. Operation loops back to step 1058 to determine if there are any other D2D links to initialize.

When all D2D links connected to the chiplet hub have been initialized, operation proceeds to step 1064 to determine if there are any child chiplets to initialize. If there are child chiplets to initialize, in step 1066 the child chiplet boot image for the particular child chiplet, be it a chiplet hub or an edge connected child chiplet, is provided to child chiplet RAM, more specifically the hub manager RAM. In step 1068, the boot operation of the child chiplet is triggered. In step 1070, it is determined if the child chiplet is a chiplet hub. If not, operation returns to step 1064 to check for more child chiplets. If so, in step 1072 the child chiplet CPU initializes the static CCS system instance and connects that static CCS system instance to the parent CCS system instance. In the case of CH-1 1004, CH-2 1006 and CH-3 1008, the parent chiplet hub would be CH-0, the root chiplet hub. Operation then returns to step 1058 for that particular chiplet hub.

If there are no more child chiplet in step 1064, in step 1074 the root hub manager obtains the interconnect system profile from its flash memory. From that profile, in step 1076 the root hub manager allocates all system resources for the entire clustered chiplet hub. In step 1077, the root hub manager allocates and sets the configuration for all components. In step 1078, the root hub manager configures all of the root chiplet hub components, i.e. the internal components in the root chiplet hub, and passes the configuration information to each child chiplet hub. In step 1080, each child chiplet hub configures the child chiplet hub components, informs the root hub manager of the completion of its configuration and proceeds to pass configuration information to any child chiplet hub, which child chiplet hub manager repeats these steps. After all of the child chiplet hubs have completed initialization of all of their chiplet hub components, the root manager root hub manager in step 1082 will understand that all of the chiplet hubs have been fully initialized, as have all of the components connected to the various chiplet hubs, and all the components can be initialized can be started in step 1082.

This has been a description of a static initialization, where all details are included in the firmware images, including routing tables, agents and services to deploy and the like. In the static initialization, the root hub manager has a simplified task of deploying the agents and services, loading the routing tables, configuring the MMUs and MMs and the like. In some embodiments a dynamic initialization is used, where the root hub manager receives higher level instructions, either from the firmware or from an external management device, describing desired system instances, memory sizes and types for each system instance, compute or accelerator requirements and the like. The root hub manager then surveys the attached and embedded devices and develops a configuration to meet the instructions. The root hub manager then configures the system 98 as determined, deploying agents and services, setting memory addresses, assigning device IDs, developing and deploying routing tables and the like.

Further, this has been a description where the root hub manager controls initialization but also controls all operations after the chiplet hub chassis instances have been merged. Should a device in a child chiplet connected CH-3 1008 request a management service, the request is routed to the root hub manager and the root hub manager performs the request. In an alternate embodiment, handling of management requests is distributed among the various hub managers, with selected requests being handled locally and other requests being forwarded to the root hub manager. This distributed management reduces loading on the root hub manager but the expense of more complex programming.

As each chiplet hub can contain different types of memory and as chiplet hubs can be interconnected, the situation arises that there may be different access times from a particular device to each of the particular memories. This is referred to as nonuniform memory access (NUMA). This is illustrated in FIG. 10C. A chiplet hub 2002 contains a fabric 2004, an SRAM 2006, a memory controller 2008 connected to HBM DRAM 2010, a memory controller 2012 connected to DRAM 2014 and an accelerator 4 2016. The chiplet hub 2002 is connected to a chiplet hub 2015. The chiplet hub 2015 includes a fabric 2018, an SRAM 2020, an internal compute 2022, a memory controller 2024 and its connected DRAM 2026 and a CXL HDM 2028. From the view of the accelerator 4 2016, the fastest memory is the SRAM 2006, followed by the HBM DRAM 2010, the DRAM 2014, the SRAM 2020, the DRAM 2026 and the CXL HDM 2028. From the viewpoint of the internal compute 2022, the fastest memory is the SRAM 2020. It is then unclear whether the next fastest memory would be the DRAM 2026 or the SRAM 2006, depending upon the link speed of the D2D link. The next fastest memory after either of the DRAM 2026 or the SRAM 2006 is the HBM DRAM 2010 and then DRAM 2014. The CXL HDM 2028 is still likely the slowest memory from the viewpoint of the internal compute 2022. Because of these relationships of the hierarchy of the memory and the location of the memory on particular chiplet hubs, the memories are all considered NUMA and if it is desired, an affinity for the particular memories can be developed for a particular device such as accelerator 4 2016 or the internal compute 2022. This is most easily done by understanding the relationship of the particular memories and the related address spaces and correctly mapping address spaces to the internal compute 2022 or the accelerator 4 2016 to allow the internal compute 2022 or the accelerator 4 2026 to utilize nonuniform memory access transactions if desired.

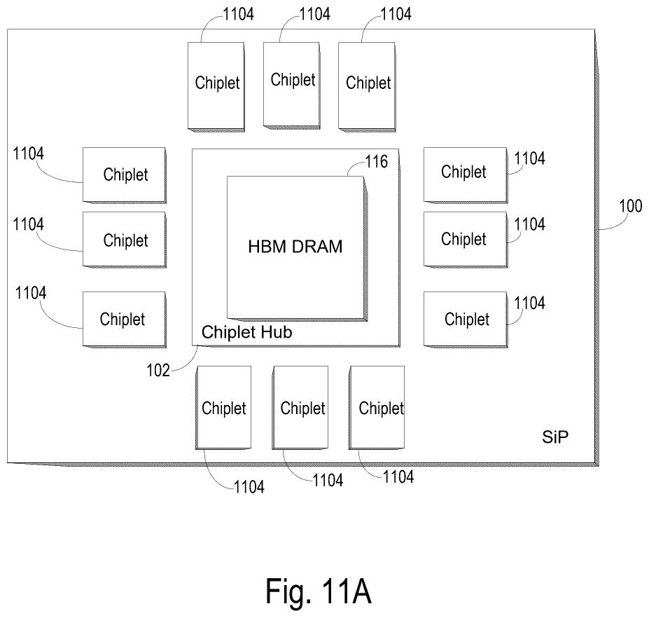

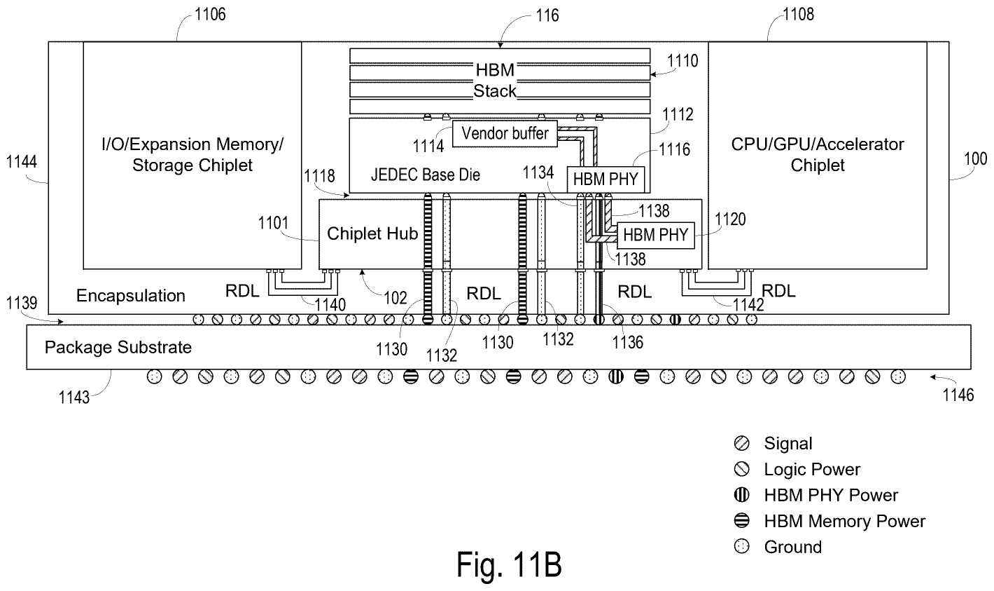

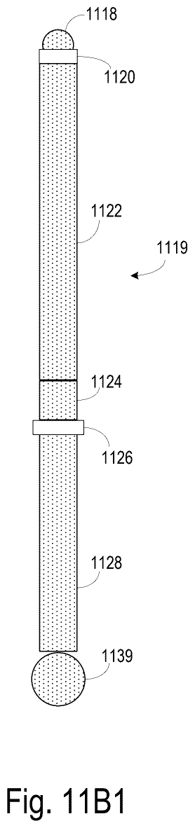

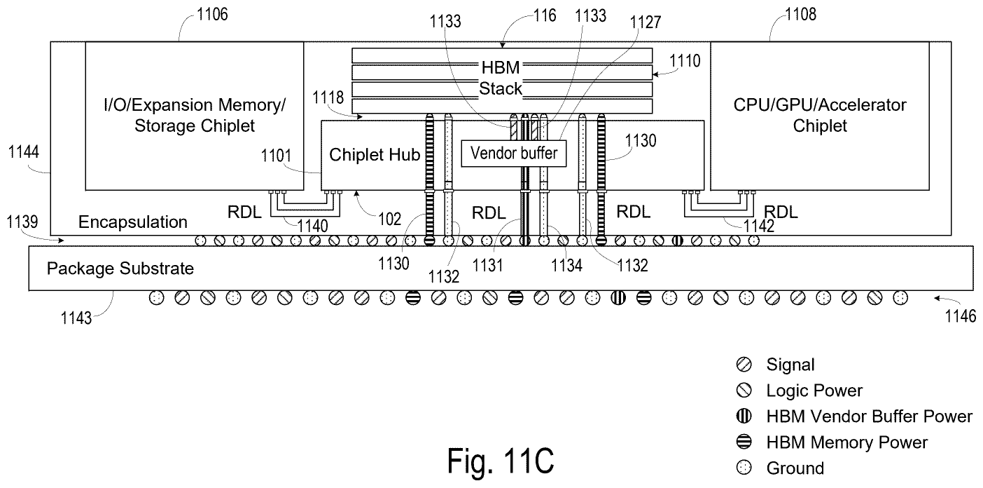

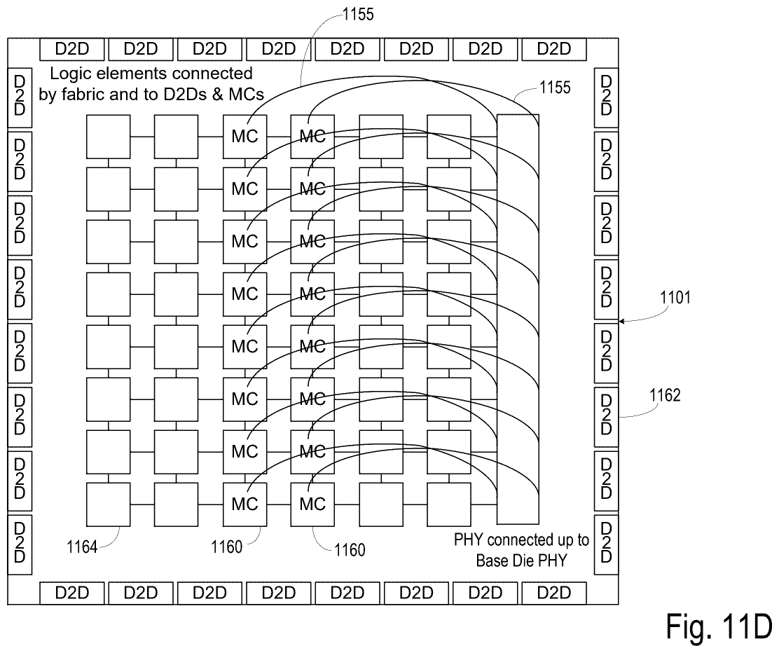

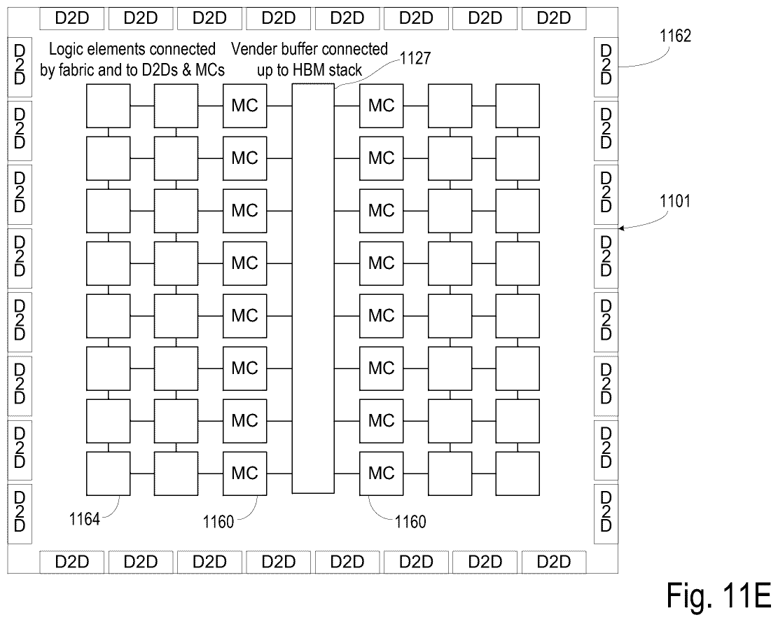

Referring now to FIG. 11A, an exemplary physical layout of the SiP 100, the chiplet hub 102 and the HBM DRAM 116 is shown. The HBM DRAM 116 is illustrated as being mounted on top of the chiplet hub 102. Various other chiplets 1104 are mounted on the SiP 100 around the chiplet hub 102.

A side view of a first embodiment for mounting the HBM DRAM 116 on the chiplet hub 102 is illustrated in FIG. 11B. The SiP 100 is formed by encapsulating the chiplet hub die 1101, the HBM DRAM 116 and other chiplets, such as an I/O/Expansion Memory/Storage chiplet 1106 and or a GPU/CPU/accelerator chiplet 1108. Preferably fan-out panel level packaging (FO-PLP) techniques are used to encapsulate the various chiplets and other devices in the SiP 100. Alternatively, fan-out wafer level packaging (FOWLP) could be used, as could other methods of assembling multiple chiplets onto a common substrate. The encapsulating resin can be applied in several different manners, with each having advantages and disadvantages.

The HBM DRAM 116 is formed by an HBM stack 1110 which contains the desired number of individual HBM chips. The HBM chips forming the HBM stack 1110 are conventional, preferably complying with the HBM3 or HBM4 specifications as provided by JEDEC. A JEDEC base die 1112 is provided under the HBM stack 1110. The HBM stack 1110 is mounted to the JEDEC base die 1112 in the conventional manner. The JEDEC base die 1112 includes a vendor buffer 1114 positioned inside the JEDEC base die 1112 in a location appropriate for receiving the various signals from the HBM stack 1110. An HBM PHY 1116 is located on one side of the JEDEC base die 1112. Signal connections are provided from the vendor buffer 1114 to the HBM PHY 1116.

The chiplet hub die 1101 includes an HBM PHY 1120 in a location complementary to the location of the HBM PHY 1116 in the JEDEC base die 1112. The JEDEC base die 1112 is connected to the chiplet hub die 1101 using a series of solder micro bumps 1118 placed over back side bonding pads 1120, though many other techniques such as hybrid bonding and the like are known and suitable. The chiplet hub die 1101 includes a series of through silicon vias (TSVs) for passing power and ground to the JEDEC base die 1112. A detailed view of a conductive path 1119 between C4 solder bumps 1139 and solder micro bumps 1118 is shown in FIG. 11B1.

At the top of the conductive path 1119 is a solder micro bump 1118. The micro solder bump 1118 is placed on a back side bonding pad 1120. A TSV 1122 projects through most of the chiplet hub die 101 until it reaches the normal metal layers 1124. The normal metal layers 1124 span the distance to a front side bonding pad 1126. A redistribution layer (RDL) column 1128 passes through the encapsulation 1138 to mate with the C4 solder bump 1139. These conductive paths 1119 are used to provide power and ground to JEDEC base die 1112 and the HBM PHY 1116.

Conductive paths 1130 carry HBM and JEDEC base die power. Conductive paths 1132 are used to provide ground to the JEDEC base die 1112. Conductive paths 1136 carry HBM PHY power. Conductive paths 1134 carry ground to the HBM PHY 1116. Signal conductive paths 1138 are similar to the conductive path 1119, except the TSVs only extend to the metal layers necessary to connect to the logic layers of the HBM PHY 1120.

The chiplet hub die 1101 is preferably connected to the I/O/Expansion Memory/Storage chiplet 1106 and the GPU/CPU/accelerator chiplet 1108 using RDLs 1140 and 1142, which are later encapsulated by the encapsulation material 1144. RDLs are preferred over silicon bridges or silicon interposer layers, though silicon bridges, silicon interposer layers or other techniques can be used to connect the chiplets.

A series of C4 solder bumps 1139 connect the encapsulated SiP 100 to the package substrate 1143. The package substrate 1143 is conventional. Similarly, the package substrate 1143 has a series of C4 solder bumps 1146 on the bottom to allow mounting to a larger printed circuit board. The C4 solder bumps 1139 and C4 solder bumps 1146 carry the various power, ground and signals used with the system 98.

While only two conductive paths 1130, a single conductive path 1136 and only three ground conductive paths 1132 and 1134 1126 are illustrated, it is understood that these are exemplary and as many as necessary to provide the needed amounts of power and ground will be utilized. Similarly, only two signal conductive paths 1138 are shown between the HBM PHY 1116 and the HBM PHY 1120 as representative. It is understood that there may be thousands of these signals because of the nature of an HBM DRAM 116. It is further understood that the remaining ground, power and signal connections for the power, ground and signals to the chiplet hub die 1101 are provided through the C4 solder bumps 1139 and 1146.

Referring now to FIG. 11C, a second alternative of the combination of the HBM DRAM 116 and the chiplet hub die 1101 is illustrated. Like elements from FIG. 11B have been numbered with like numbers in FIG. 11C. In the embodiment of FIG. 11C, the HBM stack 1110 is located directly on the chiplet hub die 1101 without the presence of an intervening layer such as the JEDEC base die 1112. The vendor buffer 1127, which is functionally equivalent to the vendor buffer 1114 except that the output signals are configured to be provided to memory controllers instead of the HBM PHY 1116, is located in the chiplet hub die 101 in the essentially the same location as present in the JEDEC base die 1112. A conductive path 1131 is present in the chiplet hub die 1101 to provide power to the vendor buffer 1127. Signal conductive paths 1133 are present to connect the vendor buffer 1127 to the HBM stack 1110 in the same manner as the vendor buffer 1114 in the JEDEC base die 1112 was connected to the HBM stack 1110.

In reviewing the side view drawings of FIG. 11B and FIG. 11C, it can be seen that the I/O/Expansion Memory/Storage chiplet 1106 and the GPU/CPU/accelerator chiplet 1108 are a height similar to the stacked height of the chiplet hub die 1101 and the HBM DRAM 116. This occurs on part because the chiplet hub die 1101 must be thinned to allow the TSVs in the conductive paths to be exposed to the back side bond pads. This allows a simple planar upper surface of the SiP 100, simplifying heat sinking or other heat transfer methods.

The embodiment of FIG. 11B using the JEDEC base die 1112 is lower-cost due to greater volume of production but also lower performance and higher power because of the need to go through the two HBM PHYs. The embodiment of FIG. 11C is higher cost as chiplet hub die 1101 must be customized to match the HBM stack 1110 from each vendor but is also higher performance and lower power. This allows the system designer to perform a trade-off between cost and performance if desired.

FIG. 11D is a representation of the physical layout of the chiplet hub die 1101 in the configuration of FIG. 11B using the JEDEC base die 1112. The HBM PHY 1120 is shown as being positioned on one side of the chiplet hub die 1101. This location aligns the HBM PHY 1116 in the JEDEC base die 1112. A series of memory controllers 1160 are connected to the HBM PHY 1120. The HBM PHY 1120 is connected to the memory controllers 1160 by fly over connections 1155, which can be envisioned as a separate layer on the chiplet hub die 1101. This allows the remaining circuitry in the chiplet hub die 1101 to be located as desired. A series of D2D PHYs 1162 are located around the periphery of the chiplet hub die 1101 to illustrate that all sides of the chiplet hub die 1101 remain available for connecting chiplets and no portion of the sides are dedicated to connecting to the HBM DRAM 116. The square blocks 1164 illustrate the logic blocks as described in the preceding figures relating to the functioning of the chiplet hub 102. The various functions such as fabric 400, agents and services and the like are located on the chiplet hub die 1101 as desired.

Referring now to FIG. 11E, the layout drawing of the chiplet hub die 1101 is provided for the second embodiment with the vendor buffer 1127. The vendor buffer 1127 is illustrated in the center of the chiplet hub die 1101. This conforms to the location of the vendor buffer 1114 in the JEDEC base die 1112, to conform to the location necessary for the HBM stack 1110. The memory controllers 1160 are connected to the vendor buffer 1127 directly, without the need for the flyover connections 1155.

The operation and functions of the chiplet hub 102 are identical in the two variants of the chiplet hub die 1101, where the HBM PHY 1120 or the vendor buffer 1147 is utilized, with the same logical flow, routing tables, resource allocation, performance tuning, etc. Referring to FIGS. 11D and 11E, it can be seen that the memory controllers 1160 are both in the middle of the chiplet hub die 1101. A SiP designed for the configuration of FIG. 11D will optimize chiplet placement around the chiplet hub, connectivity to D2D links, programming of the routing tables, etc to maximize performance and minimize fabric congestion based on its connected chiplet usage of HBM bandwidth. Once this is optimized for the FIG. 11D chiplet hub, a similar SiP can be designed using the FIG. 11E chiplet hub, and because the memory controllers are in the same spot in the middle of the fabric, all of the optimizations designed for the FIG. 11D chiplet hub can be reused. Effectively, the only difference is differing pinouts.

It has been determined that the power dissipation of the chiplet hub 102 should remain under approximately 30 W if HBM3 or HBM4 standard HBMs are used, so that the performance of the HBM stack 1110 is not affected by the thermal dissipation of the chiplet hub 102. Keeping the power consumed by the chiplet hub 102 below 30 watts allows the HBM DRAM 116 to be mounted directly on the chiplet hub 102 and not require additional space in the SiP 100 or have the concomitant memory signal routing issues when placing the HBM on the same substrate as the chiplet hub die. Further, this location of the HBM DRAM 116 on the chiplet hub 102 provides for improved performance of the HBM DRAM as opposed to an off chiplet hub or separate mounting location in the SiP by minimizing trace lengths and the like. In addition, the location of the HBM DRAM 116 on the chiplet hub 102 allows the four sides of the chiplet hub 102 to be completely available for the placement of D2D links. This increased number of D2D links, as opposed to utilizing a number of the edge to be dedicated to interacting with the HBM DRAM 116 allows for improved functionality of the SiP 100 by allowing the addition of additional chiplets connected to the chiplet hub 102. If the HBM DRAM was attempted to be placed on high power devices, such as CPU cores or accelerator agents, the performance of the HBM DRAM would be very negatively affected by the much higher power of those devices. This 30 W power limit further limits the use of connections other than a D2D connection to the chiplet hub, as the PHY of most high performance communication protocols draws significant levels of power. A CXL HDM 150 is described above as being directly attached to the chiplet hub using a CXL/PCI protocol, but the number of such ports would be very limited and care would need to be taken to minimize the power usage of the rest of the chiplet hub.

A flexible yet powerful system has been described. The use of the chiplet hub with a primary function of connecting computational chiplets, such as compute or acceleration, with a hierarchy of memory allows use of a heterogenous mix of best of breed chiplets to allow optimization of a final system based on performance or cost or a balance. Locating the HBM on the chiplet hub saves space in the SiP and provides for greater access to more D2D ports, allowing the use of a larger number of chiplets, while also allowing attached devices to be able to share the HBM. Through the use of isolated system instances, varying tasks can be performed on the system while maintaining privacy and security. The configuration of the HDMA system allows use by non-host devices and yet maintains full control of DMA operations.

The above description is intended to be illustrative, and not restrictive. For example, the above-described examples may be used in combination with each other. Many other examples will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.”

1. A system comprising:
a first memory having a first address space;
a second memory having a second address space;
a non-host device for providing direct memory access (DMA) requests, the non-host device having a non-host device address space; and
a DMA controller system including:
a request manager for receiving a DMA request for transferring data from the first memory and providing the data to the second memory, the DMA request received from the non-host device, the request manager forming a plurality of DMA commands from the DMA request; and
an agent coupled to the request manager and operating in the address spaces of the first and second memories, the agent for receiving the plurality of DMA commands from the request manager and performing a read transaction from the first memory and a write transaction to the second memory for each DMA command.

2. The system of claim 1, further comprising:
a host device for providing direct memory access (DMA) requests,
wherein the request manager further receives DMA requests from the host device.

3. The system of claim 1, wherein the first and second memories are different.

4. The system of claim 1, wherein the first and second memories are the same.

5. The system of claim 1, wherein the agent includes a multi-channel DMA controller which receives the plurality of DMA commands.

6. The system of claim 5, wherein the request manager includes a distribution controller for selecting the channel of the DMA controller to receive the plurality of DMA commands.

7. The system of claim 5, wherein the DMA request and the plurality of DMA commands are provided in the non-host device address space,
wherein the first memory address space and the second memory address space are the same,
wherein the agent includes an address translating unit for translating non-host device address space addresses in the plurality of DMA commands to first and second memory space addresses, and
wherein the translated addresses are provided to the DMA controller to perform the read transactions from the first memory and the write transactions to the second memory.

8. The system of claim 5, wherein the first memory address space and the second memory address space are different,
wherein the DMA request and the plurality of DMA commands are provided in the non-host device address space,
wherein the agent includes a first address translating unit for translating non-host device address space addresses in the plurality of DMA commands to first memory space addresses, and a second address translating unit for translating non-host device address space addresses in the plurality of DMA commands to second memory space addresses and
wherein the translated addresses are provided to the DMA controller to perform the read transactions from the first memory and the write transactions to the second memory.

9. The system of claim 5,
wherein the agent includes an endpoint emulator coupled to the DMA controller,
wherein the first memory address space and the second memory address space are the same,
wherein the DMA request and the plurality of DMA commands are provided in the non-host device address space,
wherein the DMA controller converts the DMA command into an intermediate gather request and an intermediate scatter request and provides the intermediate gather request to the endpoint emulator,
wherein the endpoint emulator utilizes the intermediate gather request to form a read transaction for performing with the first memory,
wherein the endpoint emulator receives data of a read response from the first memory and provides the data of the read response to the DMA controller,
wherein the DMA controller utilizes the data of the read response with the intermediate scatter request and provides the data of the read response and the intermediate scatter request to the endpoint emulator, and
wherein the endpoint emulator utilizes the intermediate scatter request and data from the read response to form a write transaction for performing with the second memory.

10. The system of claim 5, further comprising:
wherein the first memory address space and the second memory address space are different,
wherein the DMA request and the plurality of DMA commands are provided in the non-host device address space,
wherein the agent includes a first endpoint emulator and a second endpoint emulator coupled to the DMA controller,
wherein the DMA controller converts the DMA command into an intermediate gather request and an intermediate scatter request and provides the intermediate gather request to the first endpoint emulator,
wherein the first endpoint emulator utilizes the intermediate gather request to form a read transaction for performing with the first memory,
wherein the first endpoint emulator receives data of a read response from the first memory and provides the data of the read response to the DMA controller,
wherein the DMA controller utilizes the data of the read response with the intermediate scatter request and provides the data of the read response and the intermediate scatter request to the second endpoint emulator, and
wherein the second endpoint emulator utilizes the intermediate scatter request and data from the read response to form a write transaction for performing with the second memory.

11. The system of claim 5, wherein the first memory address space and the second memory address space are different,
wherein the DMA request and the plurality of DMA commands are provided in the non-host device address space,
wherein the agent includes an address translating unit for translating non-host device address space addresses in the plurality of DMA commands to first memory space addresses,
wherein the translated addresses are provided to the DMA controller to perform the read transactions from the first memory,
wherein the DMA controller receives data of a read response from the first memory;
wherein the agent includes an endpoint emulator coupled to the DMA controller,
wherein the DMA controller converts the DMA command into an intermediate scatter request and provides data of the read response and the intermediate scatter request to the endpoint emulator, and
wherein the endpoint emulator utilizes the intermediate scatter request and data from the read response to form a write transaction for performing with the second memory.

12. The system of claim 5, wherein the first memory address space and the second memory address space are different,
wherein the DMA request and the plurality of DMA commands are provided in the non-host device address space,
wherein the agent includes an address translating unit for translating non-host device address space addresses in the plurality of DMA commands to second memory space addresses, and
wherein the translated addresses are provided to the DMA controller to perform the write transactions to the second memory,
wherein the agent includes an endpoint emulator coupled to the DMA controller,
wherein the DMA controller converts the DMA command into an intermediate gather request and provides the intermediate gather request to the endpoint emulator,
wherein the endpoint emulator utilizes the intermediate gather request to form a read transaction for performing with the first memory,
wherein the endpoint emulator receives data of a read response from the first memory and provides the data of the read response to the DMA controller, and
wherein the DMA controller utilizes the data of the read response to form a write transaction for performing with the second memory.

13. The system of claim 1, wherein the DMA request and DMA commands are transferred in a control plane and the read and write transactions are performed in a data plane.

14. A direct memory access (DMA) controller system for transferring data between a first memory having a first address space and a second memory having a second address space based on DMA requests provided by a non-host device, the non-host device having a non-host device address space, the DMA controller system comprising:
a request manager for receiving a DMA request for transferring data from the first memory and providing the data to the second memory, the DMA request received from the non-host device, the request manager forming a plurality of DMA commands from the DMA request; and
an agent coupled to the request manager and operating in the address spaces of the first and second memories, the agent for receiving the plurality of DMA commands from the request manager and performing a read transaction from the first memory and a write transaction to the second memory for each DMA command.

15. The DMA controller system of claim 14, wherein the DMA controller system further receives DMA requests provided by a host device.

16. The DMA controller system of claim 14, wherein the DMA request and DMA commands are transferred in a control plane and the read and write transactions are performed in a data plane.

17. The DMA controller system of claim 14, wherein the agent includes a multi-channel DMA controller which receives the plurality of DMA commands.

18. The DMA controller system of claim 17, wherein the request manager includes a distribution controller for selecting the channel of the DMA controller to receive the plurality of DMA commands.

19. The DMA controller system of claim 17, wherein the DMA request and the plurality of DMA commands are provided in the non-host device address space,
wherein the first memory address space and the second memory address space are different,
wherein the agent includes an address translating unit for translating non-host device address space addresses in the plurality of DMA commands to first and second memory space addresses, and
wherein the translated addresses are provided to the DMA controller to perform the read transactions from the first memory and the write transactions to the second memory.

20. The DMA controller system of claim 17, wherein the first memory address space and the second memory address space are different,
wherein the DMA request and the plurality of DMA commands are provided in the non-host device address space,
wherein the agent includes a first address translating unit for translating non-host device address space addresses in the plurality of DMA commands to first memory space addresses, and a second address translating unit for translating non-host device address space addresses in the plurality of DMA commands to second memory space addresses and
wherein the translated addresses are provided to the DMA controller to perform the read transactions from the first memory and the write transactions to the second memory.

21. The DMA controller system of claim 17,
wherein the agent includes an endpoint emulator coupled to the DMA controller,
wherein the first memory address space and the second memory address space are the same,
wherein the DMA request and the plurality of DMA commands are provided in the non-host device address space,
wherein the DMA controller converts the DMA command into an intermediate gather request and an intermediate scatter request and provides the intermediate gather request to the endpoint emulator,
wherein the endpoint emulator utilizes the intermediate gather request to form a read transaction for performing with the first memory,
wherein the endpoint emulator receives data of a read response from the first memory and provides the data of the read response to the DMA controller,
wherein the DMA controller utilizes the data of the read response with the intermediate scatter request and provides the data of the read response and the intermediate scatter request to the endpoint emulator, and
wherein the endpoint emulator utilizes the intermediate scatter request and data from the read response to form a write transaction for performing with the second memory.

22. The DMA controller system of claim 17, further comprising:
wherein the first memory address space and the second memory address space are different,
wherein the DMA request and the plurality of DMA commands are provided in the non-host device address space,
wherein the agent includes a first endpoint emulator and a second endpoint emulator coupled to the DMA controller,
wherein the DMA controller converts the DMA command into an intermediate gather request and an intermediate scatter request and provides the intermediate gather request to the first endpoint emulator,
wherein the first endpoint emulator utilizes the intermediate gather request to form a read transaction for performing with the first memory,
wherein the first endpoint emulator receives data of a read response from the first memory and provides the data of the read response to the DMA controller,
wherein the DMA controller utilizes the data of the read response with the intermediate scatter request and provides the data of the read response and the intermediate scatter request to the second endpoint emulator, and
wherein the second endpoint emulator utilizes the intermediate scatter request and data from the read response to form a write transaction for performing with the second memory.

23. The DMA controller system of claim 17, wherein the first memory address space and the second memory address space are different,
wherein the DMA request and the plurality of DMA commands are provided in the non-host device address space,
wherein the agent includes an address translating unit for translating non-host device address space addresses in the plurality of DMA commands to first memory space addresses,
wherein the translated addresses are provided to the DMA controller to perform the read transactions from the first memory,
wherein the DMA controller receives data of a read response from the first memory;
wherein the agent includes an endpoint emulator coupled to the DMA controller,
wherein the DMA controller converts the DMA command into an intermediate scatter request and provides data of the read response and the intermediate scatter request to the endpoint emulator, and
wherein the endpoint emulator utilizes the intermediate scatter request and data from the read response to form a write transaction for performing with the second memory.

24. The DMA controller system of claim 17, wherein the first memory address space and the second memory address space are different,
wherein the DMA request and the plurality of DMA commands are provided in the non-host device address space,
wherein the agent includes an address translating unit for translating non-host device address space addresses in the plurality of DMA commands to second memory space addresses, and
wherein the translated addresses are provided to the DMA controller to perform the write transactions to the second memory,
wherein the agent includes an endpoint emulator coupled to the DMA controller,
wherein the DMA controller converts the DMA command into an intermediate gather request and provides the intermediate gather request to the endpoint emulator,
wherein the endpoint emulator utilizes the intermediate gather request to form a read transaction for performing with the first memory,
wherein the endpoint emulator receives data of a read response from the first memory and provides the data of the read response to the DMA controller, and
wherein the DMA controller utilizes the data of the read response to form a write transaction for performing with the second memory.
